(19) United States
(12) Patent Application Publication
(10) Pub. No.: US 2023/0229073 A1
(43) Pub. Date: Jul. 20, 2023

(54) METHOD OF CORRECTING A DESIGN LAYOUT OF A SEMICONDUCTOR DEVICE, A COMPUTING DEVICE PERFORMING THE SAME AND A METHOD OF FABRICATING A SEMICONDUCTOR DEVICE USING THE SAME

(71) Applicant: SAMSUNG ELECTRONICS CO., LTD., Suwon-si (KR)

(72) Inventors: Cheolhwan KIM, Suwon-si (KR); Jichang SIM, Suwon-si (KR); Jongmin LEE, Suwon-si (KR); Sangeun GO, Suwon-si (KR); Ohhun KWON, Suwon-si (KR); Hyuckjoon KWON, Suwon-si (KR)

(21) Appl. No.: 18/048,205

(22) Filed: Oct. 20, 2022

(30) Foreign Application Priority Data
Jan. 19, 2022 (KR) 10-2022-0007809
Apr. 5, 2022 (KR) 10-2022-0042030

(51) Int. Cl. G03F 1/36; G03F 1/70

(52) U.S. Cl. CPC G03F 1/36; G03F 1/70

(57) ABSTRACT

In a method of correcting a design layout of a semiconductor device, misaligned values of a portion of points of a target pattern of each of a plurality of regions of interest in a semiconductor device fabricated based on an original layout are measured, misaligned values of unmeasured points of the target pattern are estimated by using an artificial neural network trained based on the measured misaligned values of the portion of points, and a target layout of the semiconductor device is generated by using the estimated misaligned values.

### CROSS-REFERENCE TO RELATED APPLICATIONS

This application claims the benefit of priority under 35 USC § 119 to Korean Patent Application No. 10-2022-0007809, filed on Jan. 19, 2022 and to Korean Patent Application No. 10-2022-0042030, filed on Apr. 5, 2022, in the Korean Intellectual Property Office, the disclosure of each of which is incorporated by reference herein in its entirety.

### TECHNICAL FIELD

Example embodiments generally relate to semiconductor designs, and more particularly, to a method of correcting a design layout of a semiconductor device using machine learning, a computing device performing the same and a method of fabricating a semiconductor device using the same.

### DISCUSSION OF RELATED ART

In the design of an integrated circuit for a semiconductor device, a layout of the circuit may be prepared, and the layout may then be transferred to a wafer surface through a mask, such as a photomask. As semiconductor devices have become highly integrated, integrated circuit design has become more complex. Accordingly, it is becoming increasingly important to accurately implement a layout according to an originally intended design on a mask required for a lithography process. Moreover, as a wavelength of light from a light source used in exposure equipment approaches the size of features of semiconductor devices, a distortion phenomenon on a pattern may occur due to light diffraction, interference, and the like. As a result, an optical proximity effect (OPE), i.e., an unintended/distorted optical effect, may occur on a wafer during a photolithography process.

### SUMMARY

Some example embodiments may provide a method of correcting a design layout of a semiconductor device, capable of estimating misaligned values of patterns of a semiconductor device, based on a machine learning.

Some example embodiments may provide a computing device that performs a method of correcting a design layout of a semiconductor device, capable of estimating misaligned values of patterns of a semiconductor device, based on a machine learning.

Some example embodiments may provide a method of fabricating a semiconductor device using a method of correcting a design layout of a semiconductor device, capable of estimating misaligned values of patterns of a semiconductor device, based on a machine learning.

According to some example embodiments, in a method of correcting a design layout of a semiconductor device, misaligned values of a portion of points of a target pattern of each of a plurality of regions of interest in a semiconductor device fabricated based on an original layout are measured, misaligned values of unmeasured points of the target pattern are estimated using an artificial neural network trained based on the measured misaligned values of the portion of points, and a target layout of the semiconductor device is generated by using the estimated misaligned values.

According to some example embodiments, a computing device includes a plurality of processors and at least one processor of the plurality of processors performs a method of correcting a design layout of a semiconductor device by measuring misaligned values of a portion of points of a target pattern of each of a plurality of regions of interest in a semiconductor device fabricated based on an original layout, estimating misaligned values of unmeasured points of the target pattern using an artificial neural network trained based on the measured misaligned values of the portion of points and generating a target layout of the semiconductor device using the estimated misaligned values.

According to some example embodiments, in a method of fabricating a semiconductor device, an original layout associated with a design of a semiconductor device is generated, a first corrected layout by estimating misaligned values of patterns of a semiconductor device fabricated based on the original layout is generated, a second corrected layout is generated by performing optical proximity correction and position correction on the first corrected layout, a mask is generated using the second corrected layout and a target semiconductor device is fabricated using the mask.

Therefore, according to example embodiments, an original layout is corrected by measuring misaligned values of a portion of points of patterns manufactured based on an original layout and estimating misaligned values of unmeasured points based on the measuring misaligned values. Accordingly, efficiency of correction with respect to a complex structure may be enhanced and time associated with correction may be reduced.

### BRIEF DESCRIPTION OF THE DRAWINGS

The above and other features of the present disclosure will become more apparent by describing in detail example embodiments thereof with reference to the accompanying drawings.

FIG. 1 is a block diagram illustrating a semiconductor inspection system according to example embodiments.

FIG. 2 is a block diagram illustrating an example of the computing device in the semiconductor inspection system of FIG. 1 according to example embodiments.

FIGS. 3 through 6 are flow charts illustrating a method of correcting a design layout of a semiconductor device according to example embodiments.

FIG. 7 is a block diagram illustrating a semiconductor device to which a method of correcting a design layout is applicable according to example embodiments.

FIG. 8 schematically illustrates a structure of the nonvolatile memory device of FIG. 7 according to example embodiments.

FIG. 9 is a block diagram illustrating an example of the memory cell array in FIG. 7 according to example embodiments.

FIG. 10 is a circuit diagram illustrating one of the memory blocks of FIG. 9 according to example embodiments.

FIG. 11 is a layout diagram of a nonvolatile memory device according to example embodiments.

FIG. 12 is a cross-sectional view taken along a line A-A′ of FIG. 11.

FIGS. 13A and 13B illustrate a mold structure in the nonvolatile memory device of FIG. 11 according to example embodiments.

FIG. 14A is a diagram for explaining a position shifting of first patterns.

FIG. 14B illustrates a cross-sectional view of the position shifting of the first patterns in FIG. 14A.

FIG. 15 illustrates that regions of interest are set in the nonvolatile memory device according to example embodiments.

FIGS. 16 and 17 each illustrate an example of a correction sheet that can be displayed in the display when the coordinate values of the first region of interest are input to user interfaces in the computing device of FIG. 2.

FIGS. 18A, 18B and 18C illustrate examples of a network structure of a neural network model that may be included in the artificial neural network in FIG. 2.

FIGS. 19 to 21 illustrate plan views of a nonvolatile memory device according to example embodiments.

FIG. 22 is a plan view illustrating a semiconductor wafer including a plurality of semiconductor memory chips.

FIG. 23 illustrates misaligned values of patterns of a memory cell region of each of the semiconductor memory chips, captured in the semiconductor wafer in FIG. 22.

FIG. 24 illustrates an example of a semiconductor manufacturing process according to example embodiments.

FIG. 25 is a flow chart illustrating a method of fabricating a semiconductor device according to example embodiments.

### DETAILED DESCRIPTION OF THE EMBODIMENTS

Example embodiments of the present disclosure will be described more fully hereinafter with reference to the accompanying drawings. Like reference numerals may refer to like elements throughout the accompanying drawings.

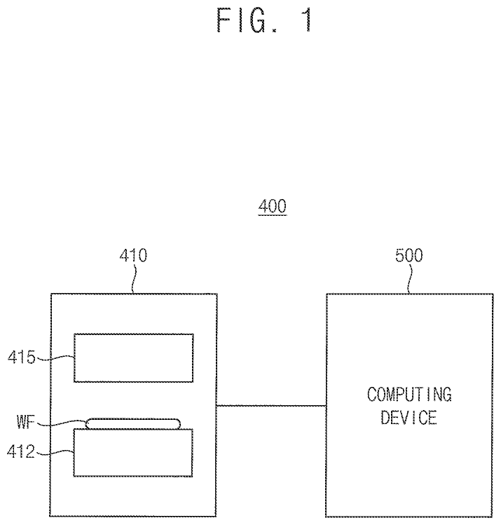

FIG. 1 is a block diagram illustrating a semiconductor inspection system according to example embodiments.

Referring to FIG. 1, a semiconductor inspection system 400 may include an image detection device 410 and a computing device 500.

The image detection device 410 may include a chuck 412 and an image measuring device 415. A wafer WF may be loaded on the chuck 412. The image measuring device 415 may obtain an image of a pattern formed on a semiconductor substrate 100 of the wafer WF. The measuring device 415 may obtain the image using a source such as an electron beam. In an example embodiment, the image detection device 410 may be a nano geometry research (NGR) device, which is a geometry verification device. In an example embodiment, the image detection device 410 may be a scanning electron microscope (SEM) device.

The computing device 500 may receive and process image data obtained from the image detection device 410.

The computing device 500 may measure misaligned values of a portion of points of a target pattern of each of a plurality of regions of interest in a semiconductor device in the wafer WF, which is fabricated based on an original layout, based on an image of patterns formed in the semiconductor device, may estimate misaligned values of unmeasured points of the target pattern using an artificial neural network that is trained based on the measured misaligned values of the portion of points and may provide a corrected layout by correcting the original layout using the estimated misaligned values.

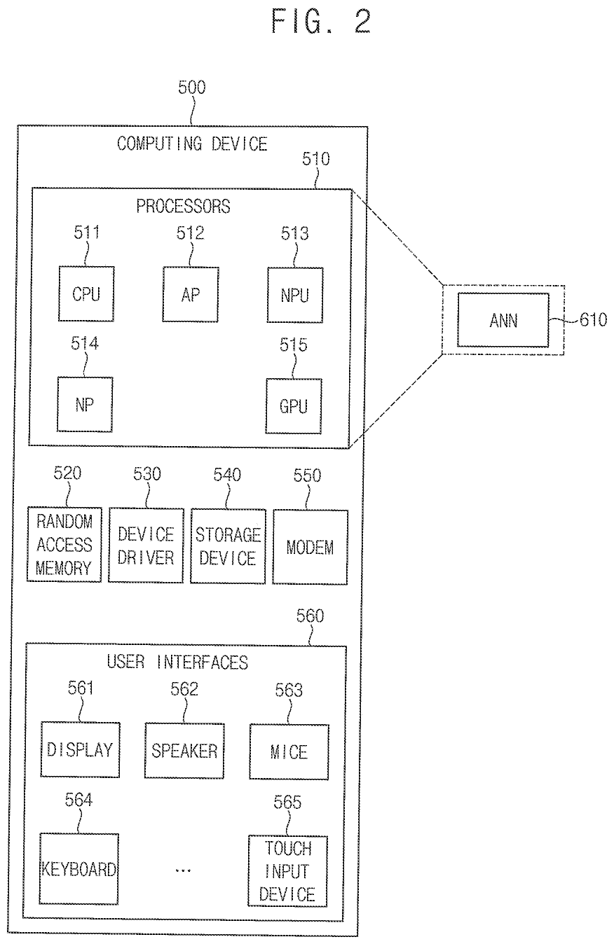

FIG. 2 is a block diagram illustrating an example of the computing device in the semiconductor inspection system of FIG. 1 according to example embodiments.

Referring to FIG. 2, a computing device 500 may include processors 510, a random access memory 520, a device driver 530, a storage device 540, a modem 550 and user interfaces 560.

At least one processor of the processors 510 may execute a semiconductor process machine learning module that is implemented with an artificial neural network (ANN) 610. The semiconductor process machine learning module may estimate misaligned values of unmeasured points of a target pattern based on machine learning and may provide a corrected layout by correcting the original layout using the estimated misaligned values.

In some example embodiments, the ANN 610 may be implemented as instructions or program codes that may be executed by the at least one of the processors 510. In this case, the at least one processor may load the instructions to the random access memory 520.

In some example embodiments, the at least one of the processors 510 may be manufactured to implement the ANN 610. For example, the at least one processor 510 may implement various machine learning modules. The at least one processor 510 may receive information corresponding to the ANN 610 to implement the ANN 610.

The processors 510 may include, for example, at least one general-purpose processor such as a central processing unit CPU 511, an application processor AP 512, etc. In addition, the processors 510 may include at least one special-purpose processor such as a neural processing unit NPU 513, a neuromorphic processor NP 514, a graphic processing unit GPU 515, etc. The processors 110 may include two or more heterogeneous processors.

The random access memory 520 may be used as an operation memory of the processors 510, a main memory or a system memory of the computing device 500. The random access memory 520 may include a volatile memory such as a dynamic random access memory (DRAM), a static random access memory (SRAM), etc., or a nonvolatile memory such as a phase-change random access memory (PRAM), a ferroelectrics random access memory (FRAM), a magnetic random access memory (MRAM), a resistive random access memory (RRAM), etc.

The device driver 530 may control peripheral circuits such as the storage device 540, the modem 550, the user interface 560, etc., according to requests of the processors 510. The storage device 540 may include a fixed storage device such as a hard disk drive, a solid state drive (SSD), etc., or an attachable storage device such as an external hard disk drive, an external SSD, a memory card, etc.

The modem 550 may perform wired or wireless communication with external devices through various communication types such as Ethernet, WiFi®, LTE®, 5G mobile communication, etc.

The user interfaces 560 may receive information from a user and provide information to the user. The user interfaces 560 may include at least one output interface such as a display 561, a speaker 562, etc., and at least one input interface such as a mouse 563, a keyboard 564, a touch input device 565, etc.

The ANN 610 may receive the instructions or codes through the modem 550 and store the instructions in the storage device 540. In some example embodiments, the instructions of the ANN 610 may be stored in an attachable storage device and the attachable storage device may be connected to the computing device 500 by a user. The instructions of the ANN 610 may be loaded to the random access memory 520 for rapid execution of the instructions.

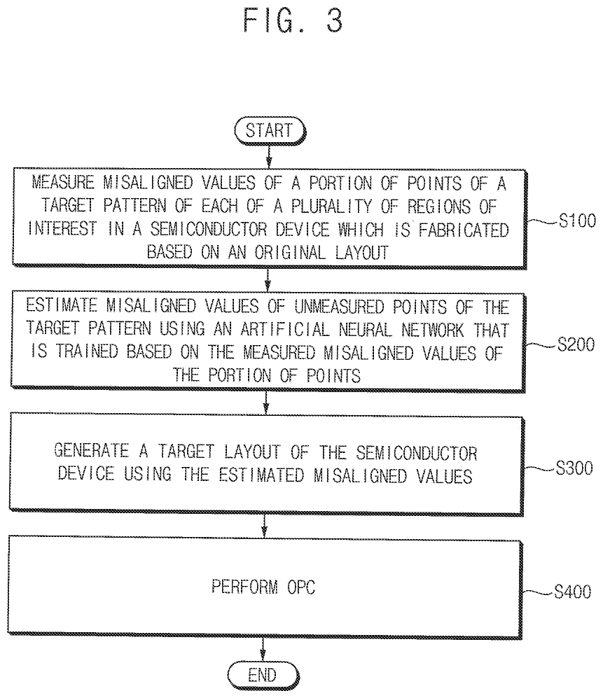

FIGS. 3 through 6 are flow charts illustrating a method of correcting a design layout of a semiconductor device according to example embodiments.

Referring to FIG. 3, for correcting a design layout of a semiconductor device, misaligned values of a portion of points of a target pattern of each of a plurality of regions of interest in a semiconductor device which is fabricated based on an original layout are measured (operation S100). Misaligned values of unmeasured points of the target pattern are estimated using an artificial neural network that is trained based on the measured misaligned values of the portion of points (operation S200).

Training of the artificial neural network may be performed using a Random Forest algorithm. The Random Forest algorithm may include a bootstrap process allowing redundancy in given data to generate a data set of the same size as a data set, and a bagging process coupling each weak learners based on data generated by the bootstrap process.

T sampling data sets having the same size as the data set may be generated using the bootstrap process based on the measured misaligned values. In addition, a learner constituting a forest may be trained and modeled, based on the T sampling data sets to be generated. The learner trained by the bootstrap process may reduce variance and maintain bias at the same time to improve performance of the learner. Finally, each of the trained and modeled learners may be bagged into a random forest. A pattern misaligned values predicting model may be generated based on the bagged random forest.

A target layout of the semiconductor device is generated using the estimated misaligned values (operation S300). An optical proximity correction (OPC) is performed on the target layout (operation S400).

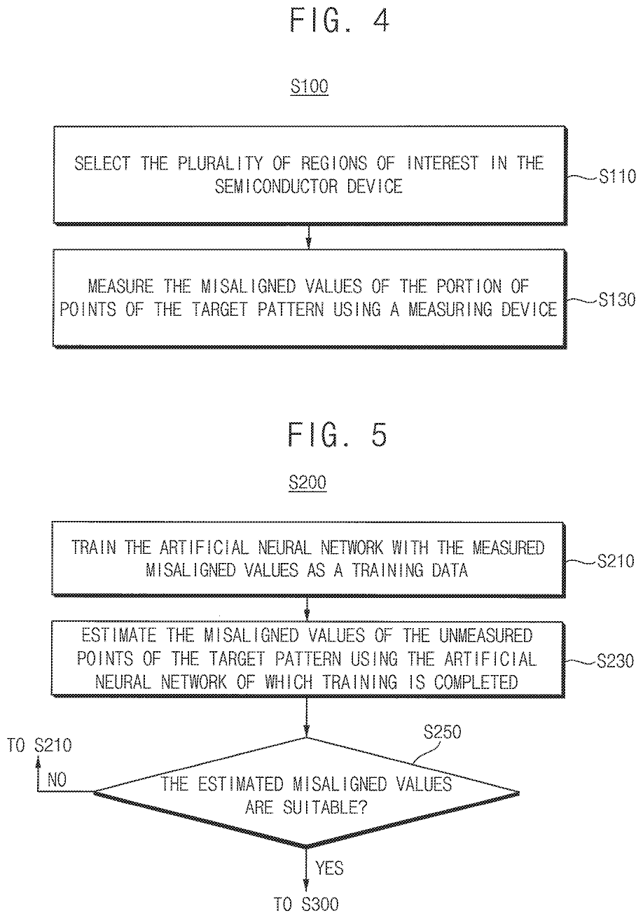

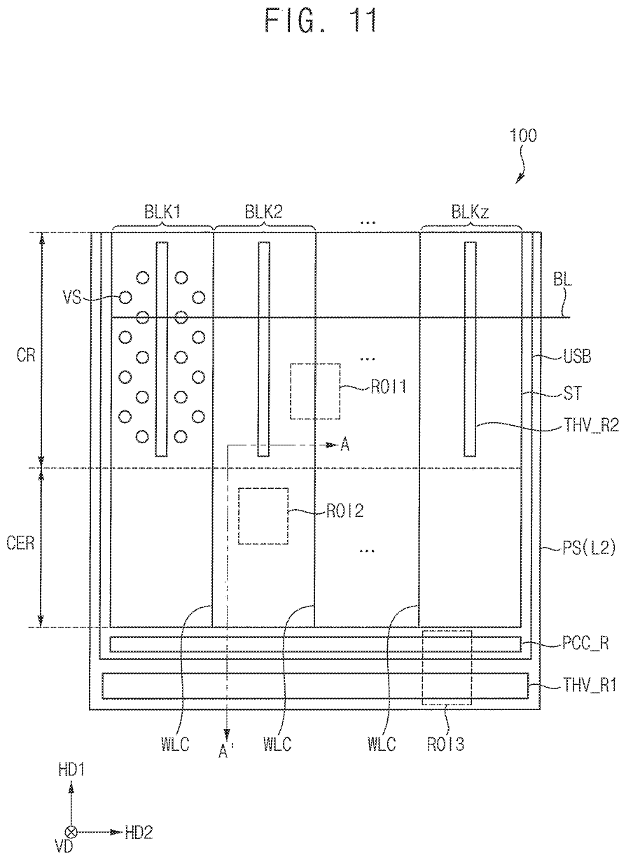

Referring to FIG. 4, for measuring the misaligned values of the portion of points (operation S100), the plurality of regions of interest (ROI1 and ROI2 in FIG. 11) are selected (or determined) in the semiconductor device (operation S110) and the misaligned values of the portion of points of the target pattern are measured using a measuring device (operation S130).

For selecting (or determining) the plurality of regions of interest ROI1 and ROI2 (operation S110), coordinate values of each of a first corner and a second corner in a diagonal direction of a rectangular representing each of the plurality of regions of interest ROI1 and ROI2 may be inputted.

Referring to FIG. 5, for estimating the misaligned values of the unmeasured points (operation S200), the artificial neural network is trained with the measured misaligned values as training data (operation S210), the misaligned values of the unmeasured points of the target pattern are estimated using the trained artificial neural network (operation S230), and the estimated misaligned values are assessed to determine whether the estimated misaligned values are correct (e.g., accurate) based on a cross-validation (operation S250).

The cross-validation may be k-fold cross-validation. The k-fold cross-validation is performed by randomly classifying the estimated misaligned values into k-fold sets having approximately the same number of pieces of data, and then, using k−1 number of sets as training sets and the single remaining set as a testing set. The k-fold cross-validation is a method in which the above-described process is repeated k times to evaluate a prediction model that is formed in the training sets with respect to the testing set. Here, k is a natural number greater than two.

When it is determined that the estimated misaligned values are not suitable (NO in operation S250), the process returns to operation S130.

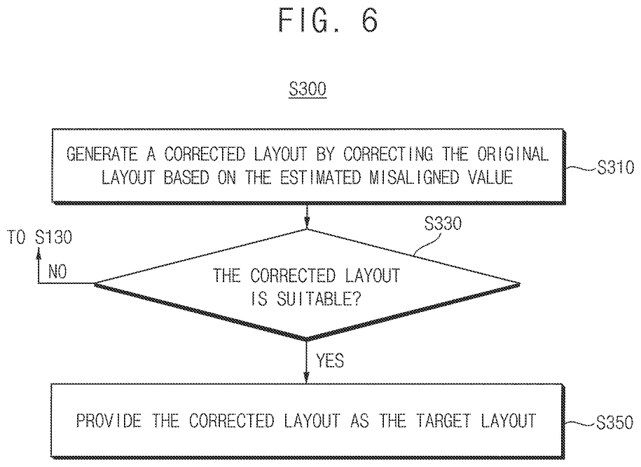

Referring to FIGS. 5 and 6, when it is determined that the estimated misaligned values are not suitable (YES in operation S250), for generating the target layout (operation S300), a corrected layout is generated by correcting the original layout based on the estimated misaligned values (operation S310), and whether the corrected layout is suitable based on values measured in the semiconductor device is determined (operation S330). When it is determined that the corrected layout is not suitable (NO in operation S330), the process returns to operation S130.

When it is determined that the corrected layout is suitable (YES in operation S330), the corrected layout is provided as the target layout (operation S350).

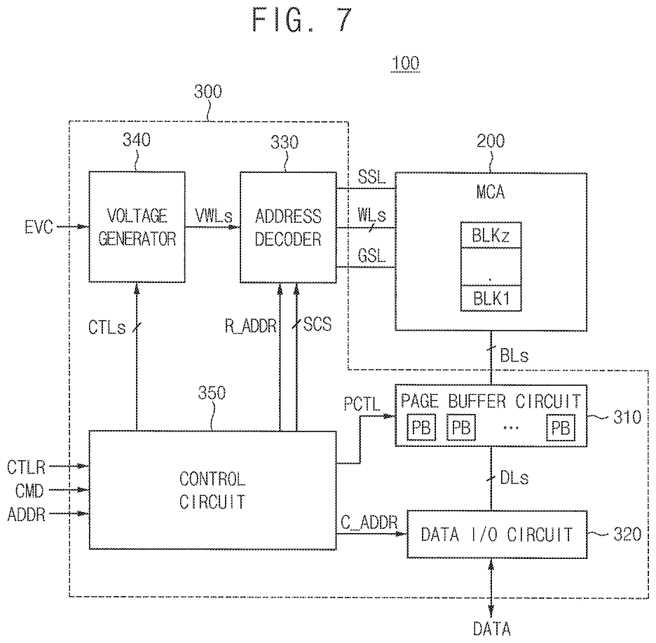

FIG. 7 is a block diagram illustrating a semiconductor device to which a method of correcting a design layout is applicable according to example embodiments.

Hereinafter, it is assumed that a semiconductor device corresponds to a nonvolatile memory device

Referring to FIG. 7, a nonvolatile memory device 100 may include a memory cell array 200 and a peripheral circuit 300. The peripheral circuit 300 may include a page buffer circuit 310, a data input/output (I/O) circuit 320, a control circuit 350, a voltage generator 340, and an address decoder 330.

The memory cell array 200 may be coupled to the address decoder 330 through a string selection line SSL, a plurality of word-lines WLs, and a ground selection line GSL.

In addition, the memory cell array 200 may be coupled to the page buffer circuit 310 through a plurality of bit-lines BLs. The memory cell array 200 may include a plurality of nonvolatile memory cells coupled to the plurality of word-lines WLs and the plurality of bit-lines BLs.

The memory cell array 200 may include a plurality of memory blocks BLK1 through BLKz, and each of the memory blocks BLK1 through BLKz may have a three-dimensional (3D) structure. Here, z is an integer greater than two. The memory cell array 200 may include a plurality of vertical cell strings (e.g., NAND strings) and each of the vertical cell strings includes a plurality of memory cells stacked with respect to each other.

The control circuit 350 may receive a command CMD, an address ADDR, and a control signal CTRL from an external memory controller and may control, for example, an erase loop, a program loop and a read operation of the nonvolatile memory device 100. The program loop may include a program operation and a program verification operation and the erase loop may include an erase operation and an erase verification operation.

In example embodiments, the control circuit 350 may generate control signals CTLs, which are used for controlling the voltage generator 340, based on the command CMD, may generate a page buffer control signal PCTL for controlling the page buffer circuit 310, may generate switching control signals SCS for controlling the address decoder 330, and may generate a row address R_ADDR and a column address C_ADDR based on the address ADDR. The control circuit 350 may provide the row address R_ADDR to the address decoder 330, may provide the column address C_ADDR to the data I/O circuit 320, may provide the control signals CTLs to the voltage generator 340 and may provide the page buffer control signal PCTL to the page buffer circuit 310.

The address decoder 330 may be coupled to the memory cell array 200 through the string selection line SSL, the plurality of word-lines WLs, and the ground selection line GSL. During program operation or read operation, the address decoder 330 may determine one of the plurality of word-lines WLs as a selected word-line based on the row address R_ADDR and may determine the rest of the plurality of word-lines WLs except the selected word-line as unselected word-lines.

The voltage generator 340 may generate word-line voltages VWLs associated with operations of the nonvolatile memory device 100 using an external voltage EVC provided from the memory controller based on control signals CTLs from the control circuit 350. The word-line voltages VWLs may be applied to the plurality of word-lines WLs through the address decoder 330.

For example, during the erase operation, the voltage generator 350 may apply an erase voltage to a well of a selected memory block and may apply a ground voltage to all word-lines of the selected memory block. During the erase verification operation, voltage generator 350 may apply an erase verification voltage to all word-lines of the selected memory block or may apply the erase verification voltage to the word-lines of the selected memory block on a word-line basis.

For example, during the program operation, the voltage generator 350 may apply a program voltage to the selected word-line and may apply a program pass voltage to the unselected word-lines. In addition, during the program verification operation, the voltage generator 350 may apply a program verification voltage to the selected word-line and may apply a verification pass voltage to the unselected word-lines. In addition, during the read operation, the voltage generator 350 may apply a read voltage to the selected word-line and may apply a read pass voltage to the unselected word-lines.

The page buffer circuit 310 may be coupled to the memory cell array 200 through the plurality of bit-lines BLs. The page buffer circuit 310 may include a plurality of page buffers PB. The page buffer circuit 310 may temporarily store data to be programmed in a selected page or data read out from the selected page of the memory cell array 200.

In example embodiments, page buffer units included in each of the plurality of page buffers PB (and cache latches included in each of the plurality of page buffers PB may be spaced apart from each other, and may have separate structures. Accordingly, the degree of freedom of wirings on the page buffer units may be increased, and the complexity of a layout may be reduced. In addition, because the cache latches are adjacent to data I/O lines, the distance between the cache latches and the data I/O lines may be reduced, and thus, data I/O speed may be increased.

The data I/O circuit 320 may be coupled to the page buffer circuit 310 through a plurality of data lines DLs. During the program operation, the data I/O circuit 320 may receive program data DATA from the memory controller and provide the program data DATA to the page buffer circuit 310 based on the column address C ADDR received from the control circuit 450. During the read operation, the data I/O circuit 320 may provide read data DATA to the memory controller based on the column address C ADDR received from the control circuit 350.

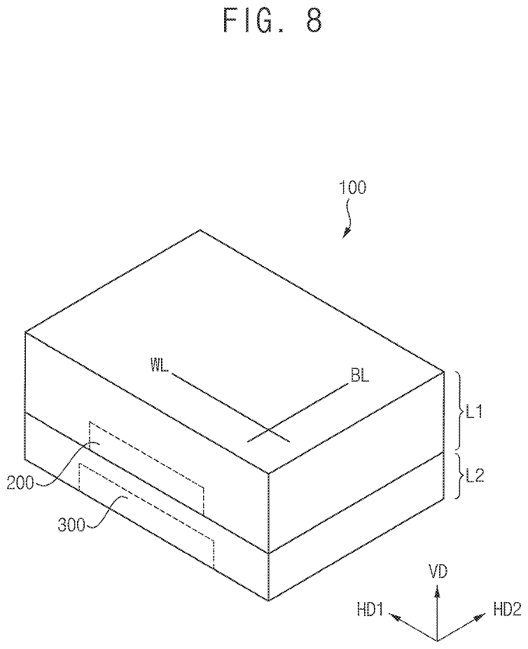

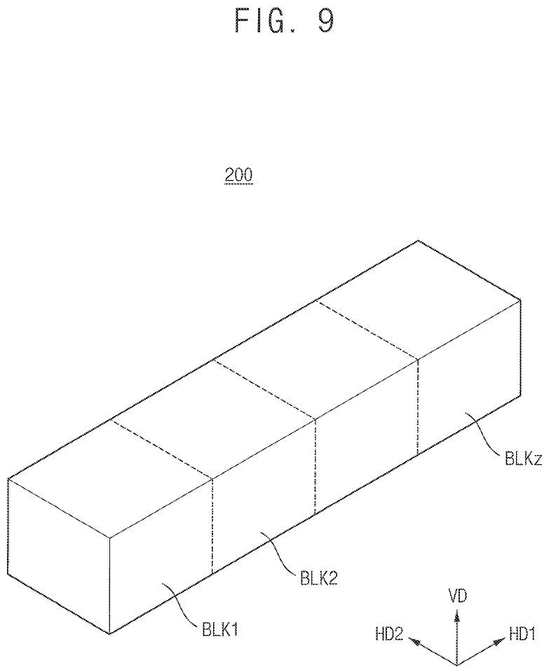

FIG. 8 schematically illustrates a structure of the nonvolatile memory device of FIG. 7 according to example embodiments.

Referring to FIG. 8, the nonvolatile memory device 100 may include a first semiconductor layer L1 and a second semiconductor layer L2. The first semiconductor layer L1 may be stacked in a vertical direction VD with respect to the second semiconductor layer L2. The second semiconductor layer L2 may be disposed under the first semiconductor layer L1 in the vertical direction VD, and accordingly, the second semiconductor layer L2 may be close to a substrate. For example, among the first semiconductor layer L1 and the second semiconductor layer L2, the second semiconductor layer L2 may be disposed closer to a substrate.

In example embodiments, the memory cell array 200 in FIG. 7 may be formed (or provided) on the first semiconductor layer L1, and the peripheral circuit 310 in FIG. 7 may be formed (or provided) on the second semiconductor layer L2.

Accordingly, the nonvolatile memory device 100 may have a structure in which the memory cell array 200 is disposed on the peripheral circuit 300, that is, a cell over periphery (COP) structure. The COP structure may effectively reduce an area in a horizontal direction and increase the degree of integration of the nonvolatile memory device 100.

In example embodiments, the second semiconductor layer L2 may include a substrate, and by forming transistors on the substrate and metal patterns for wiring transistors, the peripheral circuit 300 may be formed in the second semiconductor layer L2. After the peripheral circuit 300 is formed on the second semiconductor layer L2, the first semiconductor layer L1 including the memory cell array 200 may be formed, and the metal patterns for connecting the word-lines WL and the bit-lines BL of the memory cell array 200 to the peripheral circuit 300 formed in the second semiconductor layer L2 may be formed. For example, the word-lines WL may extend in a first horizontal direction HD1 and the bit-lines BL may extend in a second horizontal direction HD2.

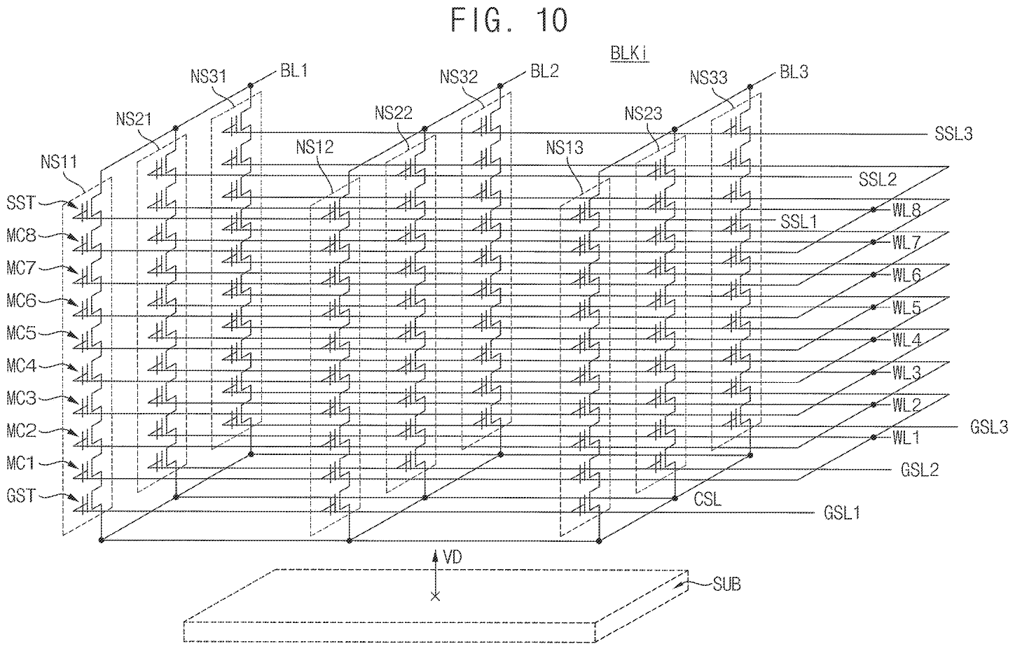

FIG. 9 is a block diagram illustrating an example of the memory cell array in FIG. 7 according to example embodiments.

Referring to FIG. 9 the memory cell array 200 may include a plurality of memory blocks BLK1 to BLKz which extend along a plurality of directions including a first horizontal direction HD1, a second horizontal direction HD2 and a vertical direction VD, in which z is a positive integer. In an embodiment, the memory blocks BLK1 to BLKz are selected by the address decoder 330 in FIG. 7. For example, the address decoder 330 may select a memory block BLK corresponding to a block address among the memory blocks BLK1 to BLKz.

FIG. 10 is a circuit diagram illustrating one of the memory blocks of FIG. 9 according to example embodiments.

The memory block BLKi of FIG. 10 may be formed on a substrate SUB in a three-dimensional structure (or a vertical structure). For example, a plurality of memory cell strings included in the memory block BLKi may be formed in the vertical direction VD substantially perpendicular to the substrate SUB. Here, i corresponds to one of 1 to z.

Referring to FIG. 10, the memory block BLKi may include memory cell strings (or, NAND strings) NS11 to NS33 coupled between bit-lines BL1, BL2 and BL3 and a common source line CSL. Each of the memory cell strings NS11 to NS33 may include a string selection transistor SST, a plurality of memory cells MC1 to MC8, and a ground selection transistor GST. In FIG. 10, each of the memory cell strings NS11 to NS33 is illustrated to include eight memory cells MC1 to MC8. However, embodiments of the present disclosure are not limited thereto. For example, in some example embodiments, each of the memory cell strings NS11 to NS33 may include any number of memory cells.

The string selection transistor SST may be connected to corresponding string selection lines SSL1 to SSL3. The plurality of memory cells MC1 to MC8 may be connected to corresponding word-lines WL1 to WL8, respectively. The ground selection transistor GST may be connected to corresponding ground selection lines GSL1 to GSL3. The string selection transistor SST may be connected to corresponding bit-lines BL1, BL2 and BL3, and the ground selection transistor GST may be connected to the common source line CSL.

Word-lines (e.g., WL1) having the same height may be commonly connected, and the ground selection lines GSL1 to GSL3 and the string selection lines SSL1 to SSL3 may be separated.

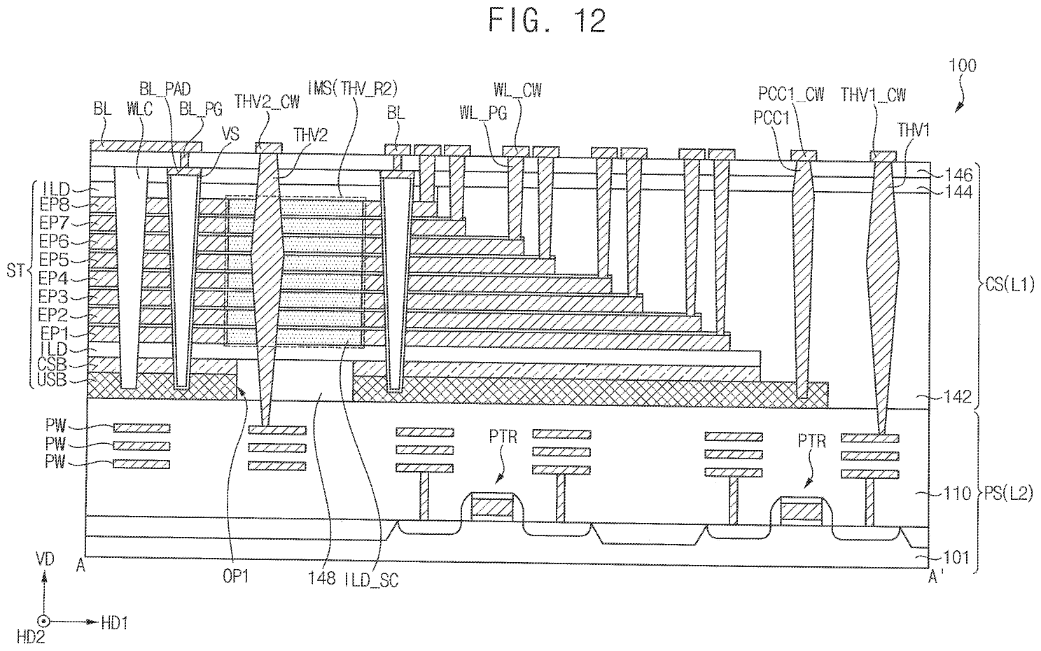

FIG. 11 is a layout diagram of a nonvolatile memory device according to example embodiments. FIG. 12 is a cross-sectional view taken along a line A-A′ of FIG. 11.

Referring to FIG. 11, a nonvolatile memory device 100 includes a peripheral logic structure PS, a horizontal conductive substrate USB, and an electrode structure ST. The peripheral logic structure PS may correspond to the second semiconductor layer L2 in FIG. 8 and the stacked structure ST may correspond to the first semiconductor layer L1 in FIG. 8. The stacked structure ST includes a cell array region CR and a cell extension region CER.

A memory cell array (e.g., 200 in FIG. 7) including a plurality of memory cells may be formed in the cell array region CR. In an example embodiment, a vertical structure VS and a bit-line BL, which will be described below, may be formed in the cell array region CR.

The cell extension region CER may be around the cell array region CR. In an example embodiment, the cell array region CR and the cell extension region CER may extend along a direction in which a word-line cut region WLC extends. In example embodiment, the cell array region CR and the cell extension region CER may extend along the first horizontal direction HD1. A plurality of electrode pads EP1 to EP8, which will be described below, may be stacked stepwise in the cell extension region CER.

The electrode structure ST may include memory blocks (e.g., BLK1 to BLKz) separated by the word-line cut region WLC.

In an example embodiment, the cell extension region CER may be on one side of the cell array region CR, as illustrated in FIG. 11. In an example embodiment, the cell extension region CER may be disposed on both sides of the cell array region CR with the cell array region CR interposed therebetween.

In an example embodiment, a single electrode structure ST may be on the peripheral logic structure PS. In an example embodiment, two or more electrode structures ST may be on the peripheral logic structure PS.

A first penetration electrode region THV_R1 may be defined by a peripheral logic structure PS that does not overlap a horizontal conductive substrate USB in the vertical direction VD. The first penetration electrode region THV_R1 may extend in the second horizontal direction HD2.

A second penetration electrode region THV_R2 may be defined by the electrode structure ST. In an example embodiment, the second penetration electrode region THV_R2 may be defined as a region extending in the first horizontal direction HD1. In an example embodiment, the second penetration electrode region THV_R2 may be defined only in the cell array region CR and not defined in the cell extension region CER. In an example embodiment, the second penetration electrode region THV_R2 may be defined in all the memory blocks BLK1 to BLKz.

A plate contact plug region PCC_R may be defined on the horizontal conductive substrate USB that does not overlap the electrode structure ST. The plate contact plug region PCC R may extend along the second horizontal direction HD1. The plate contact plug region PCC_R is defined to be closer to the electrode structure ST than the first penetration electrode region THV_R1.

The first penetration electrode region THV_R1 and the second penetration electrode region THV_R2 may be regions in which the penetration electrodes (THV1 and THV2 of FIG. 12) are disposed. The plate contact plug region PCC_R may be a region in which the plate contact plug (PCC1 of FIG. 12) is disposed. This will be described more specifically below in the description of FIG. 12.

Referring to FIGS. 11 and 12, the nonvolatile memory device 100 may include a peripheral logic structure PS and a cell array structure CS.

The peripheral logic structure PS may include a pass transistor PTR, a lower connection wiring body PW, and a peripheral logic insulation film 110. The pass transistor PTR may be on a substrate 101. The pass transistor PTR may be included in the page buffer circuit 310 in FIG. 7 or may be included in the address decoder 330 in FIG. 7.

The substrate 101 may be bulk silicon or silicon-on-insulator (SOI). In an example embodiment, the substrate 101 may be a silicon substrate or may include other material. The peripheral logic insulation film 110 may be formed on the substrate 101. The peripheral logic insulation film 110 may include, e.g., silicon oxide, silicon nitride, silicon oxynitride, or a low dielectric constant material.

The lower connection wiring body PW may be in the peripheral logic insulation film 110. The lower connection wiring body PW may be connected to the pass transistor PTR.

The cell array structure CS may include a horizontal conductive substrate USB on the peripheral logic structure PS, and an electrode structure ST on the horizontal conductive substrate USB.

The horizontal conductive substrate USB may be on the peripheral logic structure PS. The horizontal conductive substrate USB may include a first opening OP1. The first opening OP1 may expose or be open to a part of the peripheral logic structure PS.

The horizontal conductive substrate USB may be a common source plate. In an example embodiment, the horizontal conductive substrate USB may serve as the common source line CSL of FIG. 10. The horizontal conductive substrate USB may include a conductive semiconductor film, a metal silicide film, or a metal film.

In an example embodiment, the horizontal conductive substrate USB may be formed as a plurality of layers or a single layer.

A filling insulation film 148 may be on the peripheral logic structure PS. The filling insulation film 148 may fill the first opening OP1. The electrode structure ST may be on the horizontal conductive substrate USB. The electrode structure ST may cover a part of the horizontal conductive substrate USB. In an example embodiment, the horizontal conductive substrate USB may include a first region that overlaps the electrode structure ST in the vertical direction VD, and a second region that does not overlap the electrode structure ST in the vertical direction VD. The second region of the horizontal conductive substrate USB may include the plate contact plug region PCC_R in FIG. 11.

The electrode structure ST may include a plurality of electrode pads EP1, EP2, EP3, EP4, EPS, EP6, EP7 and EP8 stacked in the vertical direction VD. The electrode structure ST may include an inter-electrode insulation film ILD between the plurality of electrode pads EP1, EP2, EP3, EP4, EPS, EP6, EP7 and EP8.

The electrode structure ST may include an insulating mold part IMS. The insulating mold part IMS may overlap the first opening OP1 of the horizontal conductive substrate USB in the vertical direction VD. The insulating mold part IMS may include the second penetration electrode region THV_R2 in FIG. 11. The insulating mold part IMS may include an inter-electrode insulation film ILD and a sacrificial mold insulation film ILD SC having an etching selection ratio. The inter-electrode insulation film ILD and the sacrificial mold insulation film ILD_SC may be alternately stacked. For example, the inter-electrode insulation film ILD may include silicon oxide, and the sacrificial mold insulation film ILD SC may include silicon nitride.

The word-line cut region WLC may be disposed in the electrode structure ST. The word-line cut region WLC may extend in the first horizontal direction HD1. Each word-line cut region WLC may be spaced apart from each other in the second horizontal direction HD2. Each word-line cut region WLC may completely cut the electrode structure ST. The electrode structure ST cut by the two adjacent word-line cut region WLC may form one of the memory blocks BLK1 to BLKz.

A plurality of vertical structures VS may be on the horizontal conductive substrate USB. The plurality of vertical structures VS may penetrate the electrode structure ST. The plurality of vertical structures VS may be electrically connected to the horizontal conductive substrate USB. The vertical structures VS may include side wall parts that extend in the vertical direction VD, and a bottom part that connects the side wall parts of the vertical structure VS. The side wall parts of the vertical structures VS may have a pipe shape having a hollow space inside, e.g., a cylindrical shape or a macaroni shape.

A first interlayer insulation film 142 may be on the peripheral logic structure PS. The first interlayer insulation film 142 may cover the electrode structure ST and the horizontal conductive substrate USB. A second interlayer insulation film 144 and a third interlayer insulation film 146 may be sequentially formed on the first interlayer insulation film 142. A part of the word-line cut region WLC may extend to the second interlayer insulation film 144.

The bit-lines BL may be on the stacked structure ST. The bit-lines BL may extend in the second horizontal direction HD2. The bit lines BL may be electrically connected to at least one of the plurality of vertical structures VS.

The bit-lines BL may be on a third interlayer insulation film 146. The bit-lines BL may be electrically connected to the vertical structures VS via a bit-line pad BL_PAD and a bit-line plug BL_PG. The bit-lines BL, the bit-line pad BL_PAD, and the bit-line plug BL_PG each include a conductive material.

A plurality of electrode plugs WL_PG may be in the first to third interlayer insulation films 142, 144 and 146. The plurality of electrode plugs WL_PG may be in the cell extension region CER.

Each electrode plug WL_PG may be electrically connected to the respective electrode pads EP1 to EP8. The respective electrode plugs WL PG may connect the respective electrode pads EP1 to EP8 and a word line connection wiring WL_CW.

A first penetration electrode THV1 may be in the first penetration electrode region THV_R1. The first penetration electrode THV1 may extend in the vertical direction VD. The first penetration electrode THV1 may be in the first to third interlayer insulation films 142, 144 and 146 and the peripheral logic insulation film 110. The first penetration electrode THV1 may not penetrate the electrode structure ST. The first penetration electrode THV1 may be connected to a lower connection wiring body PW and a first penetration electrode connection wiring THV1_CW.

A first plate contact plug PCC1 may be in a plate contact plug region PCC_R. The first plate contact plug PCC1 may extend in the vertical direction VD. The first plate contact plug PCC1 may be in the first to third interlayer insulation films 142, 144 and 146. The first plate contact plug PCC1 may not penetrate the stacked structure ST.

The first plate contact plug PCC1 may be connected to the horizontal conductive substrate USB. The first plate contact plug PCC1 may be electrically connected to the horizontal conductive substrate USB in the second region of the horizontal conductive substrate USB. The first plate contact plug PCC1 may be connected to the first plate contact connection wiring PCC1_CW. A part of the first plate contact plug PCC1 may be in the horizontal conductive substrate USB.

A second penetration electrode THV2 may be in the second penetration electrode region THV_R2. The second penetration electrode THV2 may extend in the vertical direction VD. The second penetration electrode THV2 may be in the insulating mold part IMS, the filling insulation film 148, and the peripheral logic insulation film 110. The second penetration electrode THV2 may penetrate the stacked structure ST, e.g., the insulating mold part IMS. The second penetration electrode THV2 may be in the cell array region CR. The second penetration electrode THV2 may pass through the first opening OP1. The second penetration electrode THV2 may be connected to the lower connection wiring body PW and the second penetration electrode connection wiring THV2_CW.

The regions of interest ROI1, ROI2 and ROI3 may be set in the nonvolatile memory device 100. Each of the regions of interest ROI1, ROI2 and ROI3 may include at least one target pattern. The regions of interest ROI1, ROI2 and ROI3 may be selected by inputting coordinate values of each of a first corner and a second corner in a diagonal direction of a rectangular representing each of the of regions of interest ROI1, ROI2 and ROI3.

A first region of interest ROI1 may be selected (or may be set) to include the word-line cut region WLC or to include a first target pattern adjacent to a boundary between the cell array region CR and the cell extension region CER. A second region of interest ROI2 may be selected (or may be set) to include at least one of a plurality of second target patterns which are repeated in the cell extension region CER. A third region of interest ROI3 may be selected (or may be set) to include at least one of a plurality of third target patterns which are repeated in the first penetration electrode region THV_R1 and the plate contact plug region PCC_R.

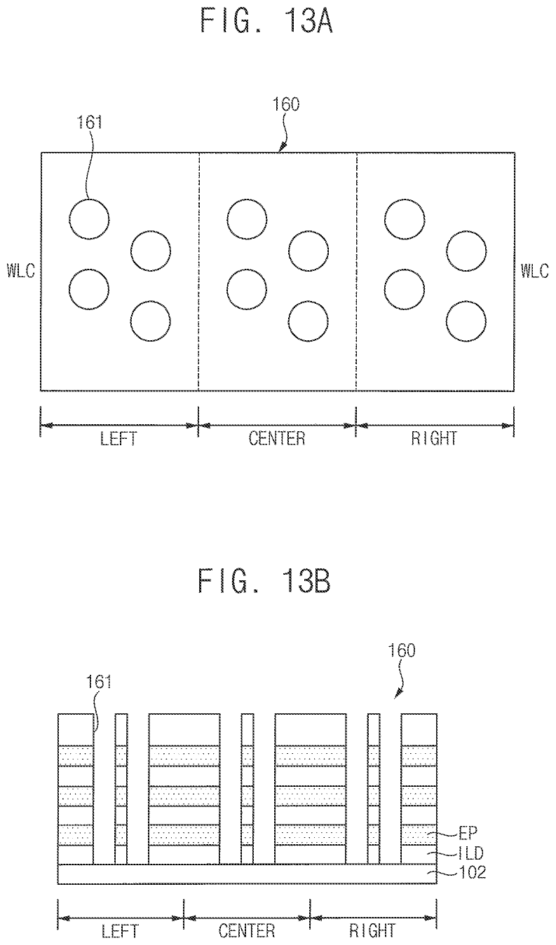

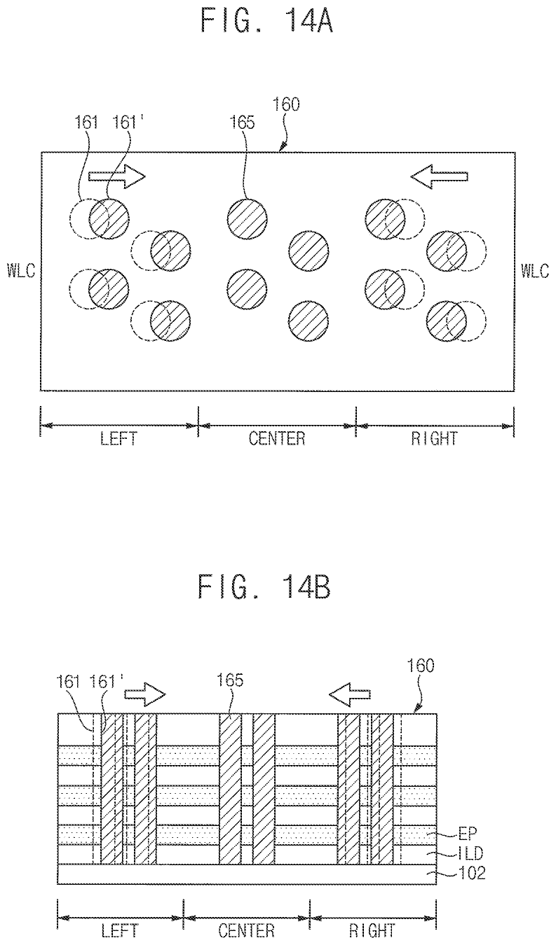

FIGS. 13A and 13B illustrate a mold structure in the nonvolatile memory device of FIG. 11 according to example embodiments.

FIG. 14A is a diagram for explaining a position shifting of first patterns and FIG. 14B illustrates a cross-sectional view of the position shifting of the first patterns in FIG. 14A.

Referring to FIGS. 13A and 13B, a mold structure 160 disposed between the word-line cut regions WLC may include multiple regions, e.g., left, center, and right regions.

As illustrated in FIG. 13A, a plurality of first patterns 161 may be formed in each of the left, center, and right regions of the mold structure 160 to be spaced apart from each other. As an example, the first patterns 161 may be channel holes vertically passing through the mold structure 100. Four first patterns 161 formed in each of the left, center, and right regions of the mold structure 160 are exemplified in FIG. 13A, but example embodiments are not limited thereto.

As illustrated in FIG. 13B, the mold structure 160 may include multiple layers ILD and EP sequentially stacked on a substrate 102. The multiple layers ILD and EP may include, e.g., multiple inter-electrode insulation layers (films) ILD and multiple electrode pads (layers) EP. The multiple inter-electrode insulation layers ILD may be sequentially stacked to be spaced apart from each other in a vertical direction. As shown in FIG. 13B, the multiple inter-electrode insulation layers ILD may be formed to extend lengthwise in a first horizontal direction. The multiple electrode layers EP may be sequentially stacked between each of the stacked multiple inter-electrode insulation layers ILD in the vertical direction. As shown in FIG. 13B, the multiple electrode layers EP may be formed to lengthwise extend in the first horizontal direction.

The first patterns 161 may lengthwise extend in the respective regions, i.e., left, center and right directions of the mold structure 160, in the vertical direction to be spaced apart from each other. The first patterns 161 may be formed to pass through the stacked multiple layers ILD and EP to expose the substrate 102. The first patterns 161 may be formed to cross the stacked multiple layers ILD and EP.

Next, as illustrated in FIGS. 14A and 14B, intermediate wiring patterns 165 filling the first patterns 161 may be formed, e.g., the intermediate wiring patterns 165 may completely fill the first patterns 161 to have the mold structure 160 with an entirely flat upper surface. The intermediate wiring patterns 165 may include information storage patterns, channel patterns, or the like. The information storage patterns may be formed on sidewalls of the first patterns 161. The channel patterns filling the first patterns 161 including the information storage patterns may be formed. The channel patterns may be made of, e.g., a semiconductor material, such as polysilicon, but example embodiments are not limited thereto. In such a manner, the information storage patterns may be disposed between the channel patterns and the stacked multiple layers ILD and EP. The information storage patterns may be formed by, e.g., a high-temperature thermal process.

FIGS. 14A and 14B illustrate that the mold structure shrinks due to a high-temperature thermal process for forming the information storage patterns.

Referring to FIGS. 14A and 14B, after filling the first patterns 161 with the intermediate wiring patterns 165, the mold structure 160 may be processed in a high-temperature thermal process to form the information storage patterns in the intermediate wiring patterns 165. However, such a high-temperature thermal process may cause the mold structure 160 to shrink toward the center region, so positions of at least some patterns of the first patterns 161 formed in the mold structure 100 may shift toward the center region, so positions of at least some patterns of the first patterns 161 formed in the mold structure 160 may shift toward the center region. Reference numeral 161 is used to denote original positions of the first patterns 161 in a case where the mold structure 160 does not undergo shrinkage (dashed lines), and reference numeral 161′ is used to denote shifted positions of the first patterns 161 in a case where the mold structure 160 shrinks (solid lines). The position shifting occurs in unit of the mold structure 160, e.g., the position shifting may occur symmetrically in left and right sides in view of the center of the mold structure 160, and the position shifting of the first patterns 161 due to shrinkage of the mold structure 160 cannot be corrected by photoresist.

In FIGS. 14A and 14B, the mold structure 160 undergoes shrinkage, which is, however, provided only for illustration, but example embodiments are not limited thereto. This may also apply to a case where the mold structure 160 undergoes expansion.

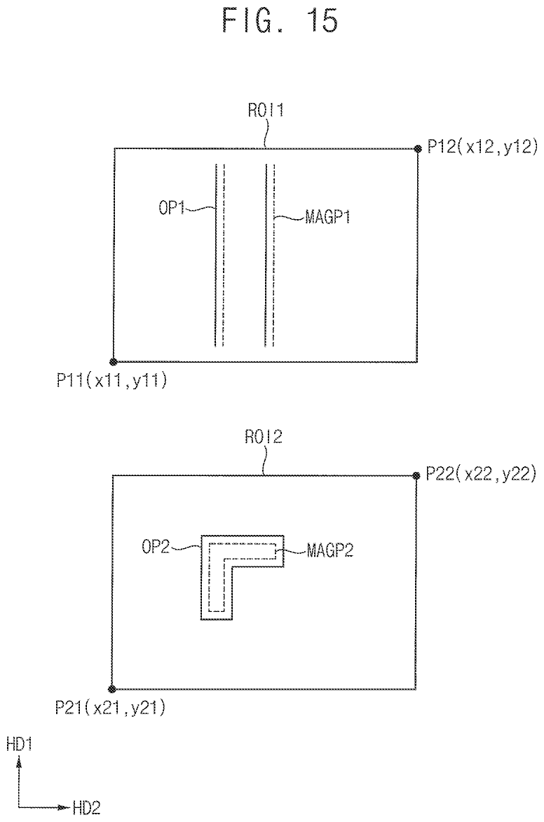

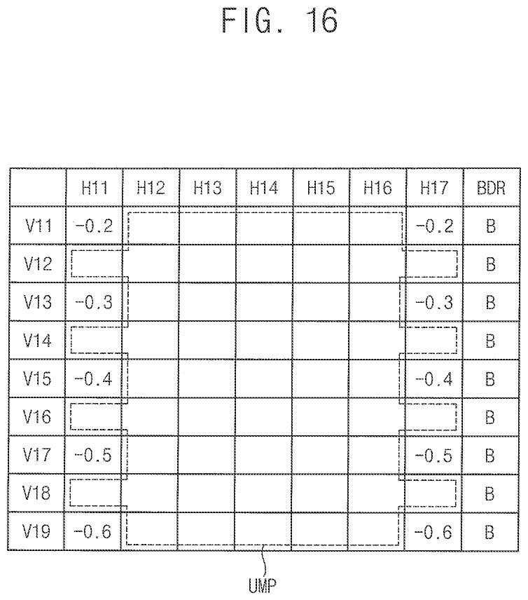

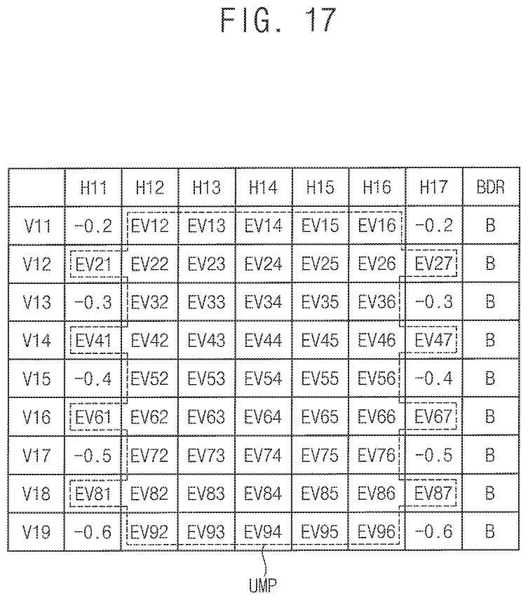

FIG. 15 illustrates that regions of interest are set in the nonvolatile memory device according to example embodiments.

Referring to FIG. 15, a first region of interest ROI1 may have a rectangular shape and may be set (i.e., selected) by inputting coordinate values (x11, y11) and (x12, y12) of a first corner C11 and a second corner C12 in a diagonal direction, of the rectangular. In addition, a second region of interest ROI2 may have a rectangular shape and may be set (i.e., selected) by inputting coordinate values (x21, y21) and (x22, y22) of a first corner C11 and a second corner C22 in a diagonal direction, of the rectangular.

A reference numeral OP1 in the first region of interest ROI1 may represent an original position of a target pattern based on the original layout and a reference numeral MAGP1 in the first region of interest ROI1 may represent a position of a target pattern that is moved and misaligned due to shrinkage. A reference numeral OP2 in the second region of interest ROI2 may represent an original position of a target pattern based on the original layout and a reference numeral MAGP2 in the second region of interest ROI2 may represent a position of a moved target pattern.

FIGS. 16 and 17 each illustrate an example of a correction sheet that is displayed in the display 561 when the coordinate values of the first region of interest are input to user interfaces in the computing device of FIG. 2.

Referring to FIG. 16, when the coordinate values (x11, y11) and (x12, y12) of the first region of interest ROI1 are input to the user interfaces 560 in the computing device of FIG. 2, a correction sheet SHEET_CR associated with a first target pattern included in the first region of interest ROI1 is displayed in the display 561. The correction sheet SHEET_CR may include first coordinate values V11˜V19, second coordinate values H11˜H17 and boundary information BDR. The first coordinate values V11˜V19 and the second coordinate values H11˜H17 may indicate a position of the first target pattern and the boundary information BDR may indicate whether the first target pattern corresponds to a boundary.

The first target pattern may be represented by a plurality of points based on combination of the first coordinate values V11˜V19 and the second coordinate values H11˜H17, misaligned values of a portion of the points are measured using the image detection device 410 in FIG. 1 and measured misaligned values (for example, −0.2, −0.3, −0.4, −0.5 and −0.6) are written in the correction sheet SHEET_CR. Misaligned values of unmeasured points UMP are not written in the correction sheet SHEET_CR.

The ANN 610 in FIG. 2 may be trained using the measured misaligned values (for example, −0.2, −0.3, −0.4, −0.5 and −0.6). Training of the ANN 610 may be performed using the Random Forest algorithm. T sampling data sets having the same size as the data set may be generated using the bootstrap process based on the measured misaligned values (for example, −0.2, −0.3, −0.4, −0.5 and −0.6). In addition, a learner constituting a forest may be trained and modeled, based on the T sampling data sets to be generated. The learner trained by the bootstrap process may reduce variance and maintain bias at the same time to improve performance of the learner. Finally, each of the trained and modeled learners may be bagged into a random forest. A pattern misaligned values predicting model may be generated based on the bagged random forest.

Referring to FIG. 17, the ANN 610 of which training is completed, may estimate misaligned values of the unmeasured points UMP based on the measured misaligned values (for example, −0.2, −0.3, −0.4, −0.5 and −0.6) and may output estimated misaligned values EV12˜EV16, EV21˜EV27, EV32˜EV36, EV41˜EV47, EV52˜EV56, EV61˜EV67, EV72˜EV76, EV81˜EV87 and EV92˜EV96.

The computing device 500 may check whether the estimated misaligned values EV12˜EV16, EV21˜EV27, EV32˜EV36, EV41˜EV47, EV52˜EV56, EV61˜EV67, EV72˜EV76, EV81˜EV87 and EV92˜EV96 are suitable through cross validation. The computing device 500 may check whether misaligned values of the first target pattern are suitable. The computing device 500 may perform k-fold cross-validation by randomly classifying the estimated misaligned values EV12˜EV16, EV21˜EV27, EV32˜EV36, EV41˜EV47, EV52˜EV56, EV61˜EV67, EV72˜EV76, EV81˜EV87 and EV92˜EV96 into k-fold sets having approximately the same number of pieces of data, and then, using k−1 number of sets as training sets and the single remaining set as a testing set.

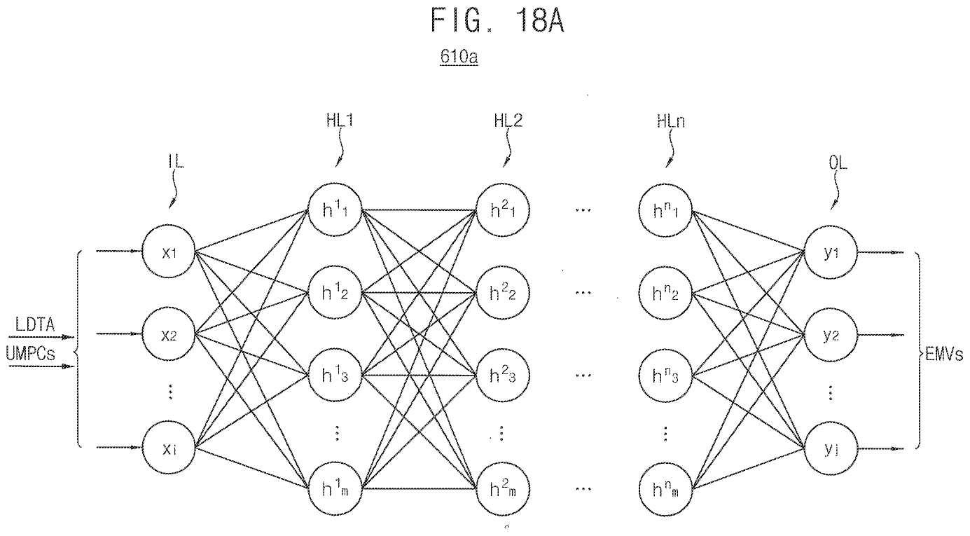

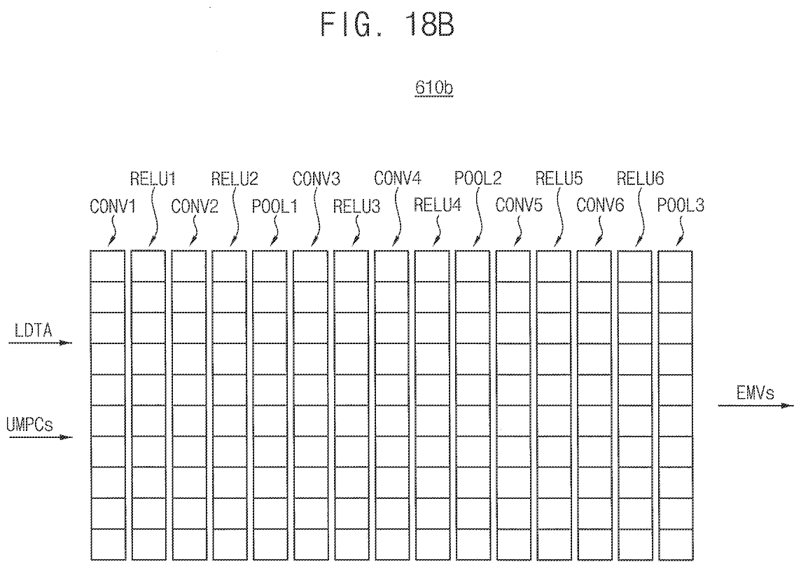

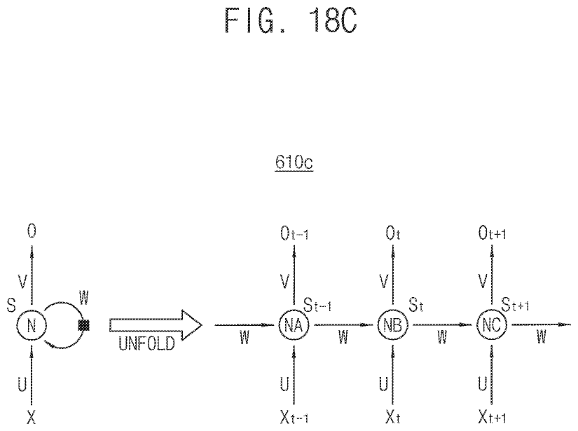

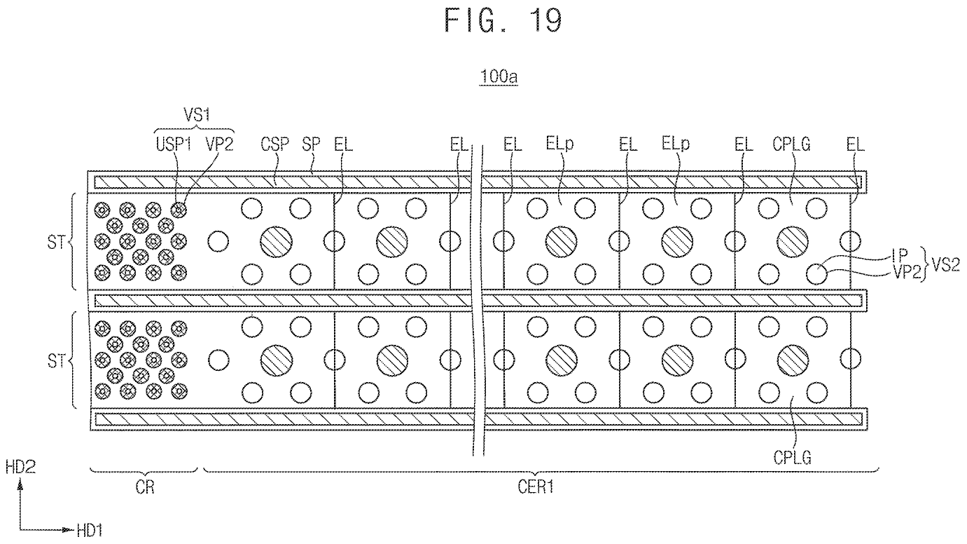

FIGS. 18A, 18B and 18C illustrate examples of a network structure of a neural network model that may be included in the artificial neural network in FIG. 2.

The neural network model may include at least one of an artificial neural network (ANN) model, a convolutional neural network (CNN) model, a recurrent neural network (RNN) model, a deep neural network (DNN) model, or the like.

Referring to FIG. 18A, a neural network 610a may include an input layer IL, a plurality of hidden layers HL1, HL2, . . . , HLn and an output layer OL.

The input layer IL may include i input nodes x₁, x₂, . . . , x₁, where i is a natural number. Learning data (e.g., training data) LDTA whose length is I and coordinate values UMPCs of unmeasured points may be input to the input nodes x₁, x₂, . . . , x₁ such that each element of the learning data LDTA and the coordinate values UMPCs of unmeasured points is input to a respective one of the input nodes x₁, x₂, . . . , xᵢ.

The plurality of hidden layers HL1, HL2, HLn may include n hidden layers, where n is a natural number, and may include a plurality of hidden nodes h¹₁, h¹₂, h¹₃, . . . , h¹ₘ, h²₁, h²₂, h²₃, . . . , h²ₘ, huⁿ₁, hⁿ₂, . . . hⁿ₃, . . . , hⁿₘ. For example, the hidden layer HL1 may include m hidden nodes h¹₁, h¹₂, h¹₃, . . . , h¹ₘ, the hidden layer HL2 may include m hidden nodes h¹₁, h¹₂, h¹₃, . . . , h²ₘ, and the hidden layer HLn may include m hidden nodes hⁿ₁, hⁿ₂, hⁿ₃, . . . , hⁿₘ, where m is a natural number.

The output layer OL may include j output nodes y1, y2, . . . , yj, where j is a natural number. Each of the output nodes y1, y2, . . . , yj may correspond to a respective one of classes to be categorized. The output layer OL may output estimated misaligned values EMVs of the unmeasured points in response to the learning data LDTA and the coordinate values UMPCs of unmeasured points. In some example embodiments, the output layer OL may be a fully-connected layer. A portion of the output nodes y1, y2, . . . yj may correspond to the estimated misaligned values EMVs.

A structure of the neural network illustrated in FIG. 18A may be represented by information on branches (or connections) between nodes illustrated as lines and a weighted value assigned to each branch, which is not illustrated. In some neural network models, nodes within one layer may not be connected to one another, but nodes of different layers may be fully or partially connected to one another. In some other neural network models, such as unrestricted Boltzmann machines, at least some nodes within one layer may also be connected to other nodes within one layer in addition to (or alternatively with) one or more nodes of other layers.

Each node (e.g., the node WO may receive an output of a previous node (e.g., the node xi), may perform a computing operation, computation or calculation on the received output, and may output a result of the computing operation, computation or calculation as an output to a next node (e.g., the node WO. Each node may calculate a value to be output by applying the input to a specific function, e.g., a nonlinear function.

In example embodiments, the structure of the neural network is set in advance and the weighted values for the connections between the nodes are set appropriately using data having an already known answer of which class the data belongs to (sometimes referred to as a “label”). The data with the already known answer is sometimes referred to as “training data”, and a process of determining the weighted value is sometimes referred to as “training”. The neural network “learns” to associate the data with corresponding labels during the training process. A group of an independently trainable structure and the weighted value is sometimes referred to as a “model”, and a process of predicting, by the model with the determined weighted value, which class the input data belongs to and then outputting the predicted value is sometimes referred to as a “testing” process.

Referring to FIG. 18B, a network structure 610b of a CNN may include a plurality of layers CONV1, RELU1, CONV2, RELU2, POOL1, CONV3, RELU3, CONV4, RELU4, POOL2, CONVS, RELUS, CONV6, RELU6 and POOL3.

Unlike the general neural network, each layer of the CNN may have three dimensions of width, height and depth, and thus data that is input to each layer may be volume data having three dimensions of width, height and depth.

Each of the convolutional layers CONV1, CONV2, CONV3, CONV4, CONVS and CONV6 may perform a convolutional operation on input.

Parameters of each convolutional layer may consist of a set of learnable filters. Every filter may be small spatially (along width and height), but may extend through the full depth of an input volume. For example, during the forward pass, each filter may be slid (e.g. convolved) across the width and height of the input volume, and dot products may be computed between the entries of the filter and the input at any position. As the filter is slid over the width and height of the input volume, a two-dimensional activation map that gives the responses of that filter at every spatial position may be generated. As a result, an output volume may be generated by stacking these activation maps along the depth dimension. For example, if input volume data having a size of 32*32*3 passes through the convolutional layer CONV1 having four filters with zero-padding, output volume data of the convolutional layer CONV1 may have a size of 32*32*12 (e.g., a depth of volume data increases).

Each of the RELU layers RELU1, RELU2, RELU3, RELU4, RELUS and RELU6 may perform a rectified linear unit (RELU) operation that corresponds to an activation function defined by, e.g., a function f(x)=max(0, x) (e.g., an output is zero for all negative input x). For example, if input volume data having a size of 32*32*12 passes through the RELU layer RELU1 to perform the rectified linear unit operation, output volume data of the RELU layer RELU1 may have a size of 32*32*12 (e.g., a size of volume data is maintained).

Each of the pooling layers POOL1, POOL2 and POOL3 may perform a down-sampling operation on input volume data along spatial dimensions of width and height. For example, four input values arranged in a 2*2 matrix formation may be converted into one output value based on a 2*2 filter. For example, a maximum value of four input values arranged in a 2*2 matrix formation may be selected based on 2*2 maximum pooling, or an average value of four input values arranged in a 2*2 matrix formation may be obtained based on 2*2 average pooling. For example, if input volume data having a size of 32*32*12 passes through the pooling layer POOL1 having a 2*2 filter, output volume data of the pooling layer POOL1 may have a size of 16*16*12 (e.g., width and height of volume data decreases, and a depth of volume data is maintained).

Typically, one convolutional layer (e.g., CONV1) and one RELU layer (e.g., RELU1) may form a pair of CONV/RELU layers in the CNN, pairs of the CONV/RELU layers may be repeatedly arranged in the CNN, and the pooling layer may be periodically inserted in the CNN.

The output layer or fully-connected layer may output estimated misaligned values EMVs of the unmeasured points in response to the learning data LDTA and the coordinate values UMPCs of unmeasured points.

Referring to FIG. 18C, a network structure 610c of an RNN may include a repeating structure using a specific node or cell N illustrated on the left side of FIG. 18C.

A structure illustrated on the right side of FIG. 18C may indicate that a recurrent connection of the RNN illustrated on the left side is unfolded (or unrolled). The term “unfolded” means that the network is written out or illustrated for the complete or entire sequence including all nodes NA, NB and NC. For example, if the sequence of interest is a sentence of 3 words, the RNN may be unfolded into a 3-layer neural network, one layer for each word (e.g., without recurrent connections or without cycles).

In the RNN in FIG. 18C, X indicates an input of the RNN. For example, Xₜ may be an input at time step v, and Xₜ₋₁ and Xₜ₊₁ may be inputs at time steps t−1 and t+1, respectively.

In the RNN in FIG. 18C, S indicates a hidden state. For example, Sₜ may be a hidden state at the time step t, and Sₜ₋₁ and Sₜ₊₁ may be hidden states at the time steps t−1 and t+1, respectively. The hidden state may be calculated based on a previous hidden state and an input at a current step. For example, Sₜ=f(UXₜ+WSₜ₋₁). For example, the function f may be usually a nonlinearity function such as tanh or RELU. S₋₁, which is required to calculate a first hidden state, may be typically initialized to all zeroes.

In the RNN in FIG. 18C, O indicates an output of the RNN. For example, Oₜ may be an output at the time step t, and Oₜ₋₁ and Oₜ₊₁ may be outputs at the time steps t−1 and t+1, respectively. For example, if it is required to predict a next word in a sentence, it would be a vector of probabilities across a vocabulary. For example, Oₜ=softmax(VSₜ).

In the RNN in FIG. 18C, the hidden state may be a “memory” of the network. For example, the RNN may have a “memory” which captures information about what has been calculated so far. The hidden state Sₜ may capture information about what happened in all the previous time steps. The output Ot_may be calculated solely based on the memory at the current time step t. In addition, unlike a traditional neural network, which uses different parameters at each layer, the RNN may share the same parameters (e.g., U, V and W in FIG. 18C) across all time steps. This may indicate the fact that the same task may be performed at each step, just with different inputs. This may greatly reduce the total number of parameters required to be trained or learned.

The RNN may output estimated misaligned values EMVs of the unmeasured points in response to the learning data LDTA and the coordinate values UMPCs of unmeasured points.

The ANN 610 may employ at least one of Support Vector Machine (SVM) and Random Forest algorithm in addition to the neural networks 610a, 610b and 610c in FIGS. 18A, 18B and 18C.

FIGS. 19 to 21 illustrate plan views of a nonvolatile memory device according to example embodiments.

Referring to FIGS. 19 to 21, each of nonvolatile memory devices 100a, 100b and 100c may include an electrode structure ST and the electrode structure ST may include a cell array region CA and respective one of cell extension regions CER1, CER2 and CER3.

The nonvolatile memory devices 100a, 100b and 100c differ from each other in that a second vertical structure VS in each of the cell extension regions CER1, CER2 and CER3 has a different configuration.

The electrode structures ST may extend in a first horizontal direction HD1 in the cell array region CR. The electrode structures ST may be spaced apart from each other in a second horizontal direction HD2.

The electrode structure ST may have a stepwise structure on the cell extension region CER. The electrode structure ST may include electrodes EL and insulation layers that are alternately and repeatedly stacked along a vertical direction perpendicular to a top surface of the substrate.

Each of the electrodes EL may have a pad ELp in the cell extension region CER.

The cell array region CR may be provided with a plurality of first vertical structures VS1 penetrating the electrode structure ST, and the cell extension region CER may be provided with a plurality of second vertical structures VS2 penetrating the electrode structure ST.

The second vertical structures VS2 may penetrate the stepwise structure of the electrode structure ST, and the number of the electrodes EL penetrated by the second vertical structures VS2 may decrease as the second vertical structures VS2 become distant from the cell array region CR.

In some embodiments, each of the first vertical structures VS1 may include a first upper semiconductor pattern USP1, and a first data storage pattern VP1. Each of the second vertical structures VS2 may include a second data storage pattern VP2, and an insulation pillar IP.

The electrode structures ST may be provided therebetween with a common source plug CSP coupled to a common source region. For example, the common source plug CSP may have a substantially uniform upper width and extend parallel to the first horizontal direction HD1. An insulation spacer SP may be interposed between the common source plug CSP and each of opposite sidewalls of the electrode structure ST. Alternatively, the common source plug CSP may penetrate the insulation spacer SP to be in partial contact with the common source region.

Cell contact plugs CPLG may penetrate the electrode structure ST to be connected to the pads ELp of the electrodes EL. The cell contact plugs CPLG may have vertical lengths that decrease with decreasing distance from the cell array region CR. The cell contact plugs CPLG may have top surfaces substantially coplanar with each other.

When viewed in plan, each of the cell contact plugs CPLG may be surrounded by the second vertical structures VS2. For example, each of the cell contact plugs CPLG may be positioned between the second vertical structures VS2 adjacent to each other.

In an embodiment illustrated in FIG. 19, the second vertical structures VS2 may penetrate the electrode structure ST on the cell extension region CER1, and ones of the second vertical structures VS2 may penetrate the pads ELp of the electrodes EL and others of the second vertical structures VS2 may penetrate boundaries between the pads ELp. The second vertical structures VS2 may be arranged in various ways.

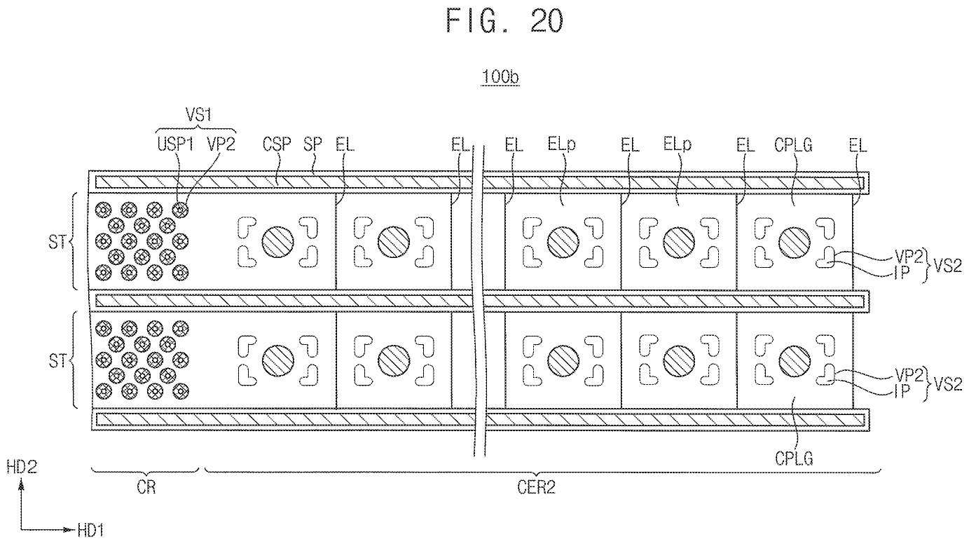

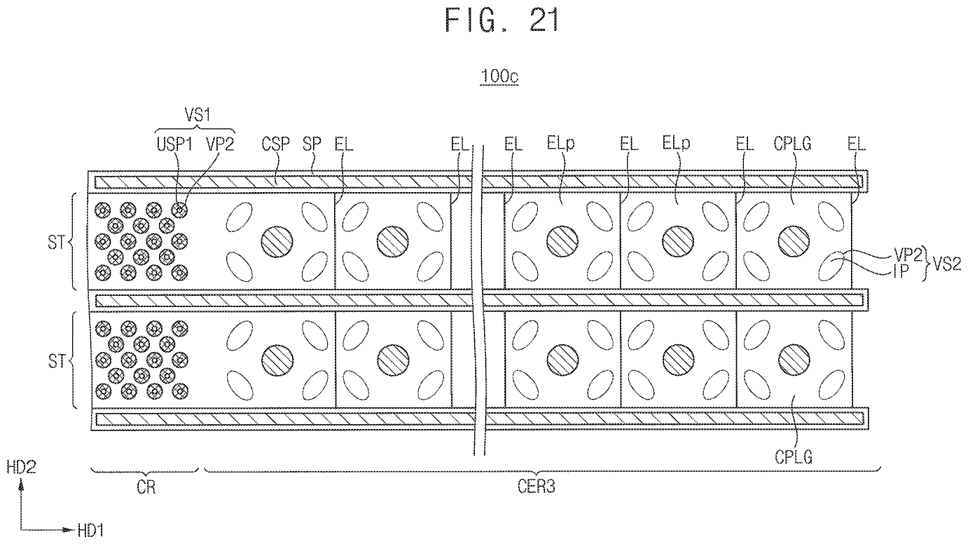

In an embodiment illustrated in FIG. 20, when viewed in plan, each of the second vertical structures VS2 may include protruding portions that extend in the first horizontal direction HD1 and the second horizontal direction HD2. The second vertical structures VS2 may be arranged to surround each of the cell contact plugs CPLG. The second vertical structures VS2 adjacent in the first horizontal direction HD1 or the second horizontal direction HD2 may be arranged at a minimum distance less than a width of each of the cell contact plugs CPLG.

In an embodiment illustrated in FIG. 21, when viewed in plan, each of the second vertical structures VS2 may have an oval shape whose major axis extends obliquely to the first and second horizontal directions HD1 and HD2. The oval-shaped second vertical structures VS2 may be arranged to surround each of the cell contact plugs CPLG.

In FIGS. 19 through 21, the common source plug CSP may correspond to the word-line cut region WLC in FIG. 1, a region adjacent to the common source plug CSP in the cell array region CAR may be set as a first region of interest and a second region of interest may be set to include the cell contact plugs CPLG or the second vertical structures VS2 in each of the cell extension regions CER1, CER2 and CER3.

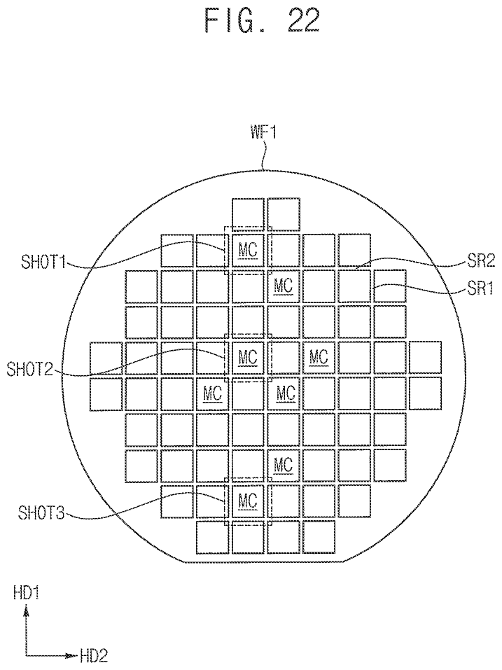

FIG. 22 is a plan view illustrating a semiconductor wafer including a plurality of semiconductor memory chips.

Referring to FIG. 22, a semiconductor wafer WF1 may include including a plurality of semiconductor memory chips MC, first scribing regions SR1 and second scribing regions SR2.

The plurality of semiconductor memory chips MC may be spaced apart from one another in a first horizontal direction HD1 and a second horizontal direction HD2 crossing the first horizontal direction HD1. The first scribing regions SR1 may be disposed between the semiconductor memory chips MC adjacent in the second horizontal direction HD2 and may extend in the first horizontal direction HD1. The second scribing regions SR2 may be disposed between the semiconductor memory chips MC adjacent in the first horizontal direction HD1 and may extend in the second horizontal direction HD2. The first scribing regions SR1 and the second scribing regions SR2 may cross each other. The plurality of semiconductor memory chips MC may be separated by cutting the first scribing regions SR1 and the second scribing regions SR2.

Each of the plurality of semiconductor memory chips MC may correspond to a nonvolatile memory device according to example embodiments.

Each of the plurality of semiconductor memory chips MC may be fabricated by estimating misaligned values of patterns manufactured based on an original layout, based on a machine learning, generating a corrected layout based on the estimated misaligned values and manufacturing the semiconductor memory chips MC based on the corrected layout, as described with reference to FIGS. 1 through 18.

In FIG. 22, a reference numeral SHOT1 indicates that patterns of a memory cell region of each of the semiconductor memory chips MC is captured by an SEM in an upper portion of the semiconductor wafer WF1, a reference numeral SHOT2 indicates that patterns of a memory cell region of each of the semiconductor memory chips MC is captured by an SEM in a middle portion of the semiconductor wafer WF1, an a reference numeral SHOT3 indicates that patterns of a memory cell region of each of the semiconductor memory chips MC is captured by an SEM in a lower portion of the semiconductor wafer WF1.

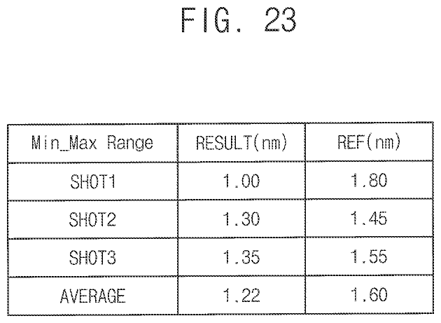

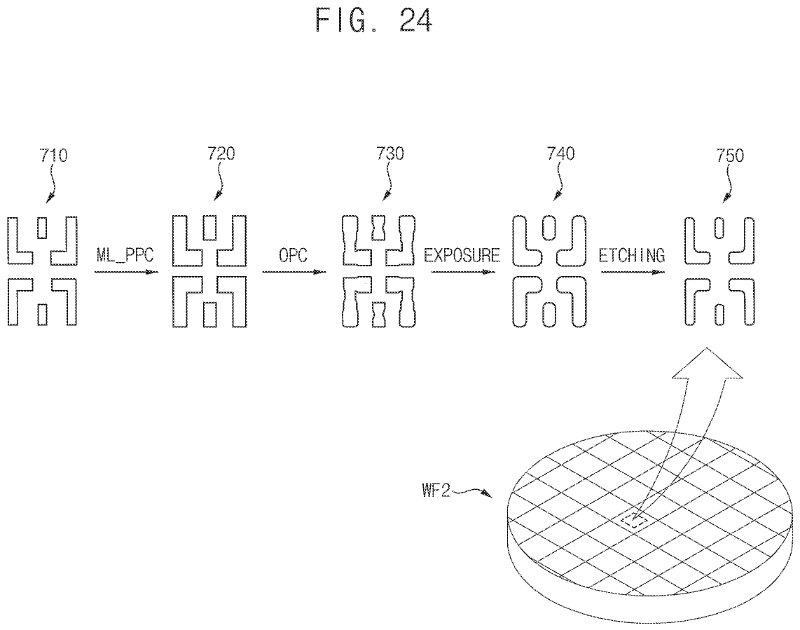

FIG. 23 illustrates misaligned values of patterns of a memory cell region of each of the semiconductor memory chips, captured in the semiconductor wafer in FIG. 22.

In FIG. 23, a result RESULT indicates misaligned values of patterns of a memory cell region fabricated according to a corrected layout based on a machine learning and a reference REF indicates misaligned values of patterns of a memory cell region according to a layout corrected manually.

Referring to FIG. 23, it is noted that the misaligned values of patterns of a memory cell region fabricated according to a corrected layout based on a machine learning, according to example embodiments are reduced compared with a case of a reference REF.

FIG. 24 illustrates an example of semiconductor manufacturing process according to example embodiments.

A semiconductor manufacturing process may include various processes such as a deposition process, an etching process, and a polishing process, as examples. Various patterns may be formed on a semiconductor substrate and/or layers formed on the semiconductor substrate by the semiconductor manufacturing process. In some example embodiments, patterns may be formed using a mask formed from layout data having a shape corresponding to the patterns. However, errors may occur while forming a mask or masks from the layout data and/or while performing a process using the formed mask or masks, such as a deposition process, an etching process, a polishing process, or another process. These errors may result in a difference between a shape of patterns included in the layout data and a shape of actual patterns formed by a semiconductor manufacturing process.

Referring to FIG. 24, original layout data 710 may be generated. The original layout data 710 may indicate a design for patterns to be formed. As an example, the original layout data 710 may be provided as data in a graphic design system (GDS) format. According to some example embodiments, a design rule check (DRC) operation for the original layout data 710 and/or a layout versus schematic (LVS) operation for verifying whether layout data matches original intended data may be performed.

In some embodiments, when the original layout data 710 is generated and/or verified through the above operations, process proximity correction based on a machine learning (ML_PPC) may be performed on the original layout data 710 to generate corrected layout data 720. The ML_PPC may be performed by estimating misaligned values of patterns manufactured based on an original layout, based on a machine learning and generating a corrected layout based on the estimated misaligned values as described with reference to FIGS. 1 through 18.

At least some patterns included in the corrected layout data 720 may have a shape and/or a size that differs from a shape and/or a size of corresponding patterns included in the original layout data 710. An optical proximity correction operation may be performed using the corrected layout data 720 to compensate for an optical proximity effect that occurs or may occur in an exposure process, and mask data 730 may be obtained as a result of the optical proximity correction operation.

The exposure process may be performed using the mask data 730. As an example, the exposure process may be performed by irradiating light to pass through the patterns included in the mask data 730 or by irradiating light to pass through a region excluding the patterns included in the mask data 730, and a mask layer 740 may be obtained. Patterns included in the mask layer 740 may have a shape and/or a size that differs from a shape and/or a size of the corresponding patterns included in the mask data 730 due to the optical proximity effect occurring in the exposure process.

A semiconductor manufacturing process may be performed using the mask layer 40 to form physical or actual patterns 750 on a semiconductor substrate WF2. As an example, in an etching process, the semiconductor substrate WF2 and/or layers on the semiconductor substrate WF2 may be etched in a region exposed by patterns included in the mask layer 740. The etched region may be a region not covered with the patterns included in the mask layer 740. In some example embodiments, the semiconductor substrate WF2 may be a wafer including a semiconductor material.

Any differences between the patterns included in the layout data 710 and 720 prior to generation of the mask data 730 and the actual patterns 750 formed on the semiconductor substrate WF2 by a semiconductor manufacturing process may be reduced. Reducing the difference between the layout data 710 and the actual patterns 750 may improve accuracy and yield of the semiconductor manufacturing process.

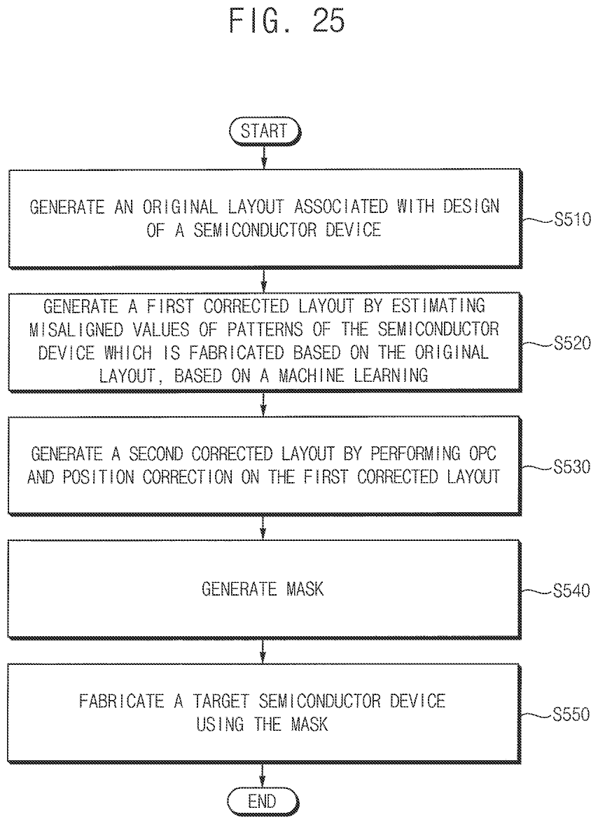

FIG. 25 is a flow chart illustrating a method of fabricating a semiconductor device according to example embodiments.

Referring to FIG. 25, a semiconductor device may be fabricated by generating an original layout associated with a design of a semiconductor device (operation S510), generating a first corrected layout by estimating misaligned values of patterns of a semiconductor device which is fabricated based on the original layout, based on a machine learning (operation S520), generating a second corrected layout by performing optical proximity correction (OPC) and position correction on the first corrected layout (operation S530), generating a mask using the second corrected layout (operation S540) and fabricating a target semiconductor device using the mask (operation S550).

For generating the original layout associated with a design of a semiconductor device (operation S510), a design layout corresponding to a circuit pattern of a semiconductor device to be formed on a wafer may be provided from a host computer, a server of a semiconductor manufacturing facility, or other suitable method. The host computer or the server may correspond to the computing device 500 of FIG. 2.

In detail, the layout is a physical indication in which a circuit designed for a semiconductor device could be transferred onto a wafer, and may include a plurality of patterns. For example, the design layout may be provided from a coordinate value of an outline of patterns forming the design layout from a CAD system. In detail, the patterns may include repetitive patterns in which the same shape is repeated, and the patterns may be provided in the form of a combination of polygons such as a triangle and/or a quadrangle.

For generating a first corrected layout by estimating misaligned values of patterns (operation S520), the ANN 610 may estimate misaligned values of patterns manufactured based on an original layout, based on a machine learning and may provide a corrected layout by correcting the original layout based on the estimated misaligned values as described with reference to FIGS. 1 through 18.

For performing OPC and position correction on the first corrected layout (operation S530), OPC is performed and position correction is performed.

The OPC refers to correction of changing patterns included in the design layout by reflecting an error according to the optical proximity effect (OPE). As a pattern is finer, an optical proximity phenomenon may occur due to influence between neighboring patterns during an exposure process. Thus, by performing OPC to correct the design layout, occurrence of the optical proximity effect may be suppressed. For example, the OPC may include expanding an overall size of the patterns forming the design layout and processing a corner portion. For example, the OPC may include moving edges of each pattern or adding additional polygons. Due to the OPC, a distortion phenomenon of a pattern, caused by diffraction, interference, and the like, of light beams generated during exposure, is corrected, and an error caused by pattern density may be corrected. After the OPC, optical proximity correction verification may further be performed.

The position correction may include moving a position of the pattern on which the optical proximity correction is performed in consideration of physical transformation and change of a lower structure in which the patterns are to be aligned. The deformation of the lower structure occurs due to a factor during a process of manufacturing a semiconductor device. As a result, progressive misalignment may occur, in which an actual pattern position of patterns of the lower structure is changed from an original layout. The position correction may not change a shape of a pattern on which the optical proximity correction is performed, but move a position thereof.

Final design layout data, corrected by the optical proximity correction and the position correction, may be transferred to exposure equipment for manufacturing a mask for a lithography process such as a photomask and an electron beam mask.

For generating the mask using the second corrected layout (operation S540), a mask may be generated according to the second corrected layout data. An exposure process is performed on a mask substrate using the second corrected layout data, to manufacture a mask. After the exposure process, for example, a series of processes such as development, etching, cleaning, baking, and the like, may be further performed to form the mask. According to example embodiments, before the second corrected layout data is transferred, verification for the corrected design layout data may be further performed.

For fabricating a target semiconductor device using the mask (operation S550), a lithography process may be performed using the mask. The semiconductor device may include a volatile memory such as a dynamic random access memory (DRAM) and a static random access memory (SRAM), or a non-volatile memory such as a flash memory, and may include a logic semiconductor device such as a microprocessor, for example, a central processing unit (CPU), a controller, or an application specific integrated circuit (ASIC). In detail, the semiconductor device may be manufactured by forming second repetitive patterns on a lower structure including first repetitive patterns. The second repetitive patterns may be aligned in high accuracy with the first repetitive patterns by the mask. The semiconductor device may be ultimately manufactured by further performing a deposition process, an etching process, an ion implantation process, a cleaning process, and the like, in addition to the lithography process.

Embodiments of the present disclosure may be applied to three-dimensional semiconductor memory devices having complex structure.

While the present disclosure has been particularly shown and described with reference to example embodiments thereof, it will be understood by those of ordinary skill in the art that various changes in form and detail may be made therein without departing from the scope of the present disclosure as defined by the following claims.

What is claimed is:

1. A method of correcting a design layout of a semiconductor device, the method comprising:
measuring misaligned values of a portion of points of a target pattern of each of a plurality of regions of interest in a semiconductor device fabricated based on an original layout;
estimating misaligned values of unmeasured points of the target pattern using an artificial neural network trained based on the measured misaligned values of the portion of points; and
generating a target layout of the semiconductor device using the estimated misaligned values.

2. The method of claim 1, further comprising fabricating the semiconductor device based on the original layout before performing the measuring misaligned values, and wherein the measuring misaligned values of the portion of points comprises:
selecting the plurality of regions of interest in the semiconductor device; and
measuring the misaligned values of the portion of points of the target pattern using a measuring device.

3. The method of claim 2, wherein the selecting the plurality of regions of interest comprises:
inputting coordinate values of each of a first corner and a second corner in a diagonal direction of a respective rectangle representing each of the plurality of regions of interest.

4. The method of claim 2, wherein the measuring device comprises a scanning electronic microscope or a Nano Geometry Research (NGR) device.

5. The method of claim 1, wherein the estimating misaligned values of the unmeasured points comprises:
training the artificial neural network with the measured misaligned values;
estimating the misaligned values of the unmeasured points of the target pattern using the trained artificial neural network; and
determining whether the estimated misaligned values are correct.

6. The method of claim 5, wherein determining whether the estimated misaligned values are correct comprises:
performing k-fold cross-validation on the estimated misaligned values, wherein k is a natural number greater than two.

7. The method of claim 6, wherein the performing k-fold cross-validation comprises:
randomly classifying the estimated misaligned values into k-fold sets; and
using k−1 number of sets of the k-fold sets as training sets and a single remaining set of the k-fold sets as a testing set.

8. The method of claim 1, wherein, in response to the estimated misaligned values being correct, the generating the target layout comprises:
generating a corrected layout by correcting the original layout based on the estimated misaligned values;
determining whether the corrected layout is correct based on values measured in the semiconductor device; and
in response to the corrected layout being correct, providing the corrected layout as the target layout.

9. The method of claim 1, wherein the artificial neural network comprises:
a plurality of input nodes;
a plurality of output nodes; and
a plurality of hidden nodes connected between the plurality of input nodes and the plurality of output nodes, and
wherein a portion of the plurality of output nodes correspond to the estimated misaligned values.

10. The method of claim 1, further comprising:
training the artificial neural network using a Random Forest algorithm.

11. The method of claim 1, wherein the semiconductor device comprises:
a first semiconductor layer comprising:
an upper substrate comprising a plurality of word-lines extending in a first horizontal direction, at least one string selection line, at least one ground selection line, and a plurality of bit-lines extending in a second horizontal direction substantially perpendicular to the first horizontal direction; and
a memory cell array comprising at least one memory block on the upper substrate; and
a second semiconductor layer under the first semiconductor layer in a direction substantially perpendicular to the first and second horizontal directions, wherein the second semiconductor layer comprises a lower substrate and a peripheral circuit configured to control the memory cell array, wherein the peripheral circuit is on the lower substrate,
wherein the at least one memory block comprises a cell array region comprising a plurality of memory cells and a cell extension region on a side of the cell region in the first horizontal direction.

12. The method of claim 11, wherein the plurality of regions of interest comprises;
a first region of interest that comprises a first target pattern adjacent to a boundary between the cell array region and the cell extension region; and
a second region of interest that comprises at least one of a plurality of second target patterns which are repeated in the cell extension region.

13. The method of claim 12, wherein:
a progressive misalignment occurs in the target pattern due to a fabrication process of the semiconductor process; and
the progressive misalignment is corrected using the estimated misaligned values.

14. The method of claim 12, wherein:
a local misalignment occurs in each of the second target patterns due to a shape of each of the second target patterns; and
a same misaligned value is applied to the local misalignment based on pattern matching.

15. The method of claim 1, wherein the semiconductor device comprises:
a semiconductor layer that comprises a cell array region and a cell extension region on a side of the cell array region in a first horizontal direction;
a plurality of first structures on the cell array region and extending in a direction perpendicular to a top surface of the semiconductor layer; and
a plurality of second structures on the second region and extending in the direction,
wherein each of the first structures comprises:
a semiconductor pattern extending in the direction and contacting the semiconductor layer; and
a first data storage pattern extending around a periphery of the semiconductor pattern, and
wherein each of the second structures comprises:
an insulation structure extending in the direction and contacting the semiconductor layer; and
a second data storage pattern extending around a periphery of the insulation structure.

16. The method of claim 15, wherein the plurality of regions of interest comprise;
a first region of interest that comprises a semiconductor pattern and a first data storage pattern which are adjacent to a boundary between the cell array region and the cell extension region; and
a second region of interest that comprises at least one of a plurality of second target patterns repeated in the cell extension region.

17. A computing device comprising:
a plurality of processors, at least one processor of the plurality of processors configured to perform a method of correcting a design layout of a semiconductor device, the method comprising:
measuring misaligned values of a portion of points of a target pattern of each of a plurality of regions of interest in a semiconductor device fabricated based on an original layout;
estimating misaligned values of unmeasured points of the target pattern using an artificial neural network trained based on the measured misaligned values of the portion of points; and
generating a target layout of the semiconductor device using the estimated misaligned values.

18. The computing device of claim 17, further comprising:
a random access memory,
wherein at least one processor of the plurality of processors is configured to load program codes of the artificial neural network to the random access memory and to execute the loaded program codes.

19. A method of fabricating a semiconductor device, the method comprising:
generating an original layout associated with a design of a semiconductor device;
generating a first corrected layout by estimating misaligned values of patterns of the semiconductor device fabricated based on the original layout;
generating a second corrected layout by performing optical proximity correction and position correction on the first corrected layout;
generating a mask using the second corrected layout; and
fabricating a target semiconductor device using the mask.

20. The method of claim 19, wherein the generating the first corrected layout comprises:
measuring misaligned values of a portion of points of a target pattern of each of a plurality of regions of interest in the semiconductor device fabricated based on the original layout;
estimating misaligned values of unmeasured points of the target pattern using an artificial neural network trained based on the measured misaligned values of the portion of points; and
providing the first corrected layout using the estimated misaligned values.
